(19) United States
(12) Patent Application Publication
(10) Pub. No.: US 2026/0047120 A1
(43) Pub. Date: Feb. 12, 2026

(54) GATE-ALL-AROUND DEVICE AND METHOD OF FORMING SAME

(71) Applicant: Tokyo Electron Limited, Tokyo (JP)

(72) Inventors: Ivo Otto, IV, Albany, NY (US); Subhadeep Kal, Albany, NY (US); Toshiki Kanaki, Albany, NY (US)

(21) Appl. No.: 18/796,731

(22) Filed: Aug. 7, 2024

(51) Int. Cl. H01L 29/66; H01L 21/02; H01L 21/28; H01L 21/306; H01L 21/324; H01L 29/06; H01L 29/423; H01L 29/775; H01L 29/786

(52) U.S. Cl. CPC H10D 30/014; H01L 21/02057; H01L 21/02532; H01L 21/306; H01L 21/324; H10D 64/017; H01L 21/28255; H10D 30/43; H10D 30/6735; H10D 30/6757; H10D 62/121

(57) ABSTRACT

A method includes forming a stack of semiconductor layers over a substrate. The stack includes a first layer including a first semiconductor material over the substrate, a second layer including a second semiconductor material over the first layer, a third layer including the first semiconductor material over the second layer, and a fourth layer including a third semiconductor material over the third layer. The method further includes patterning the stack to form a semiconductor structure, forming a sacrificial gate over the semiconductor structure, forming epitaxial regions adjacent to the sacrificial gate, removing the sacrificial gate to form a recess, selectively removing the first layer and the third layer from the semiconductor structure through the recess to form an opening, selectively removing the second layer from the semiconductor structure through the recess to expand the opening, and forming a replacement gate in the recess and the opening.

### TECHNICAL FIELD

The present disclosure relates generally to a system and method for forming semiconductor devices, and, in particular embodiments, to a system and method for forming gate-all-around (GAA) devices.

### BACKGROUND

Gate-all-around (GAA) transistors have emerged as a promising technology for advanced semiconductor devices, offering improved electrostatic control and scalability compared to traditional planar and FinFET architectures. As conventional transistor scaling approaches its physical limits, GAA structures enable continued performance improvements and power efficiency in integrated circuits. These devices feature a gate that completely surrounds the channel region, typically in a nanowire or nanosheet configuration, allowing for better control of short-channel effects and reduced leakage current. The unique geometry of GAA transistors provides enhanced carrier mobility and improved on-state current, making them ideal candidates for high-performance, low-power applications in future integrated circuits.

### SUMMARY

In accordance with an embodiment of the present disclosure, a method includes forming a stack of semiconductor layers over a substrate. The stack includes a first layer including a first semiconductor material over the substrate, a second layer including a second semiconductor material over the first layer, a third layer including the first semiconductor material over the second layer, and a fourth layer including a third semiconductor material over the third layer. The method further includes patterning the stack to form a semiconductor structure, forming a sacrificial gate over the semiconductor structure, forming epitaxial regions adjacent to the sacrificial gate, removing the sacrificial gate to form a recess, selectively removing the first layer and the third layer from the semiconductor structure through the recess to form an opening, selectively removing the second layer from the semiconductor structure through the recess to expand the opening, and forming a replacement gate in the recess and the opening.

In accordance with another embodiment of the present disclosure, a method includes forming a stack of semiconductor layers on a substrate. The stack includes a first silicon germanium (SiGe) layer on the substrate. The first SiGe layer having a first germanium (Ge) concentration. The stack further includes a second SiGe layer on the first SiGe layer. The second SiGe layer having a second SiGe concentration greater than the first Ge concentration. The stack further includes a third SiGe layer on the second SiGe layer and a silicon (Si) layer on the third SiGe layer. The third SiGe layer having the first Ge concentration. The method further includes patterning the stack to form a semiconductor structure, forming a sacrificial gate over the semiconductor structure, forming epitaxial regions adjacent to the sacrificial gate, removing the sacrificial gate to form a recess, selectively etching the first SiGe layer and the third SiGe layer through the recess to form an opening, selectively etching the second SiGe layer through the recess to expand the opening, and forming a replacement gate in the recess and the opening.

In accordance with yet another embodiment of the present disclosure, a method includes forming a stack of semiconductor layers over a substrate. The stack includes a first layer including a first semiconductor material over the substrate, a second layer including a second semiconductor material over the first layer, a third layer including the first semiconductor material over the second layer, and a fourth layer including a third semiconductor material over the third layer. The method further includes patterning the stack to form a first semiconductor structure and a second semiconductor structure, forming a first sacrificial gate over the first semiconductor structure, and forming a second sacrificial gate over the second semiconductor structure. The first sacrificial gate has a first width. The second sacrificial gate has a second width greater than the first width. The method further includes forming first epitaxial regions adjacent to the first sacrificial gate, forming second epitaxial regions adjacent to the second sacrificial gate, removing the first sacrificial gate to form a first recess, removing the second sacrificial gate to form a second recess, selectively removing the first layer and the third layer from the first semiconductor structure through the first recess to form a first opening, selectively removing the first layer and the third layer from the second semiconductor structure through the second recess to form a second opening, selectively removing the second layer from the first semiconductor structure through the first recess to expand the first opening, selectively removing the second layer from the second semiconductor structure through the second recess to expand the second opening, forming a first replacement gate in the first recess and the first opening, and forming a second replacement gate in the second recess and the second opening.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-13A and 1B-13B illustrate cross-sectional views of intermediate stages in the manufacturing of a semiconductor device including gate-all-around devices in accordance with various embodiments;

FIG. 14 illustrates a dependence of an etch rate of silicon germanium material on a germanium concentration for two different etch processes; and

FIGS. 15A-15D illustrate a flow diagram of a method for forming a semiconductor device including gate-all-around devices in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

In an embodiment, a method for fabricating a semiconductor device includes forming a multilayer stack on a substrate. The stack comprises four layers repeated one or more times. A first layer and a third layer comprise silicon germanium (SiGe) with a lower germanium concentration, a second layer comprises SiGe with a higher germanium concentration, and a fourth layer comprises silicon. The method further includes patterning the stack to create semiconductor structures, forming sacrificial gates, and creating epitaxial regions. The process then involves removing the sacrificial gates and selectively etching the SiGe layers using different etch processes tailored to the germanium concentrations. Finally, replacement gates are formed in the resulting cavities.

This approach offers several advantages in semiconductor device fabrication. The use of SiGe layers with different germanium concentrations allows for more precise control during the channel release process. By employing separate etch processes for the different SiGe layers, the method may achieve improved selectivity and may reduce or avoid silicon loss across variable nanosheet lengths. This enhanced control over the etching process may contribute to a wider process window and may improve device performance and yield. The integration of lower germanium content SiGe layers into the initial stack provides additional flexibility in tailoring the device structure and properties.

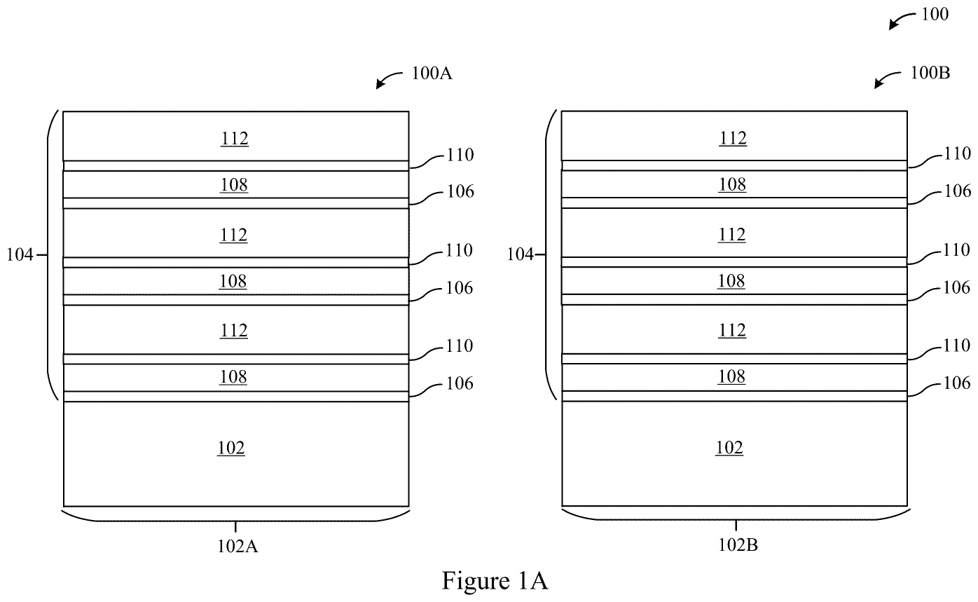

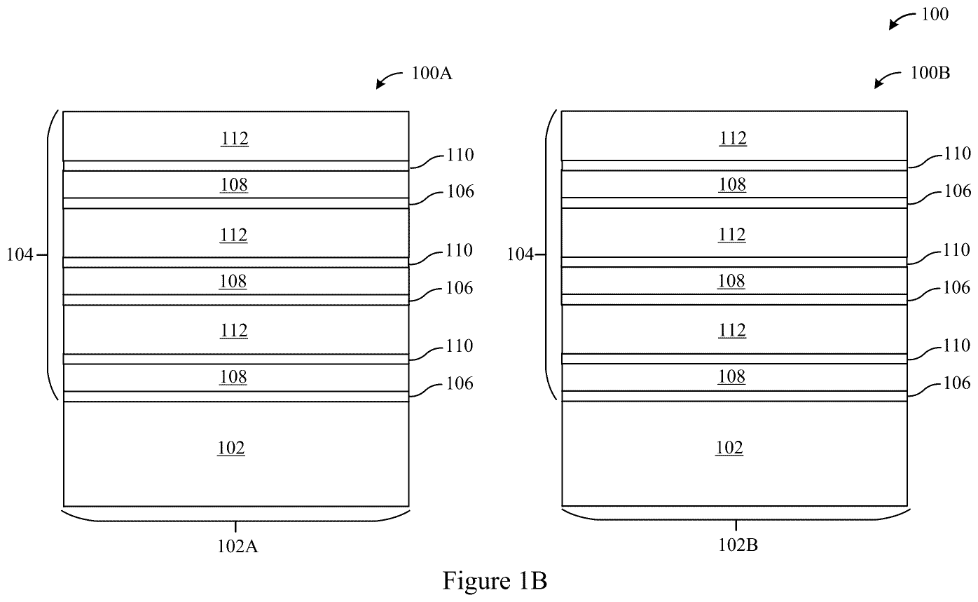

FIGS. 1A-13A and 1B-13B illustrate cross-sectional views of intermediate stages in the manufacturing of a semiconductor device 100 including gate-all-around devices in accordance with various embodiments. FIGS. 1A-13A illustrate views along a first cross-section that is along a current flow direction of gate-all-around devices. FIGS. 1B-13B illustrate views along a second cross-section that is along a second direction perpendicular to the current flow direction of gate-all-around devices, with the second cross-section being interposed between source and drain regions of gate-all-around devices.

In FIGS. 1A-13A and 1B-13B, the substrate 102 is shown divided into a first region 102A and a second region 102B. These regions may correspond to different device areas or may be used to form different types of semiconductor devices. In an embodiment, a gate-all-around device 100A having a short channel length may be formed in the first region 102A of the substrate 102 and a gate-all-around device 100B having a long channel length may be formed in the second region 102B of the substrate 102.

In FIGS. 1A and 1B, the semiconductor device 100 comprises a substrate 102 and a stack 104 of semiconductor layers formed over the substrate 102. The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate.

The stack 104 includes multiple alternating layers of different semiconductor materials. In some embodiments, the stack 104 comprises one or more first layers 106 of a first semiconductor material, one or more second layers 108 of a second semiconductor material, one or more third layers 110 of the first semiconductor material, and one or more fourth layers 112 of a third semiconductor material. In an embodiment, the first semiconductor material may be silicon germanium (SiGe) with a first germanium concentration, the second semiconductor material may be SiGe with a second germanium concentration higher than the first germanium concentration, and the third semiconductor material may be silicon (Si).

In various embodiments, the first layers 106 and the third layers 110 may comprise SiGe with a germanium concentration in a range from 10 atomic percent to 15 atomic percent and the second layers 108 may comprise SiGe with a germanium concentration in a range from 20 atomic percent to 25 atomic percent. This configuration of alternating SiGe layers with different germanium concentrations provides enhanced control over subsequent etching processes during the channel release process.

The first layers 106 may have a thickness in a range from 0.5 nm to 2.0 nm. The second layers 108 may have a thickness in a range from 5.0 nm to 10.0 nm. The third layers 110 may have a thickness in a range from 0.5 nm to 2.0 nm. The fourth layers 112 may have a thickness in a range from 5.0 nm to 10.0 nm. In some embodiments, the first layers 106 and the third layers 110 may have a same thickness. In other embodiments, the first layers 106 and the third layers 110 may have different thicknesses.

The stack 104 is formed uniformly over both the first region 102A and the second region 102B of the substrate 102. This uniform formation of the stack 104 allows for simultaneous processing of multiple device regions, enhancing manufacturing efficiency. In one or more embodiments, the thickness and composition of each layer in the stack 104 may be controlled by using deposition techniques such as chemical vapor deposition (CVD), molecular beam epitaxy (MBE), or atomic layer deposition (ALD). In some embodiments, the first layer 106 is formed over the substrate 102, the second layer 108 is formed over the first layer 106, the third layer 110 is formed over the second layer 108, and the fourth layer 112 is formed over the third layer 110. This sequence of layers may be repeated one or more times to achieve the desired height for the stack 104. In the illustrated embodiment, the sequence of layers is repeated three time. In other embodiments, the sequence of layers may be repeat more or less than three times.

The structure illustrated in FIGS. 1A and 1B serves as a starting point for subsequent processing steps that will form active device regions, such as transistor channels, in the stack 104. The alternating layers of different semiconductor materials in the stack 104 enable the formation of advanced device structures, such as nanosheet transistors or gate-all-around (GAA) transistors, which offer improved performance and scalability compared to conventional planar transistor architectures.

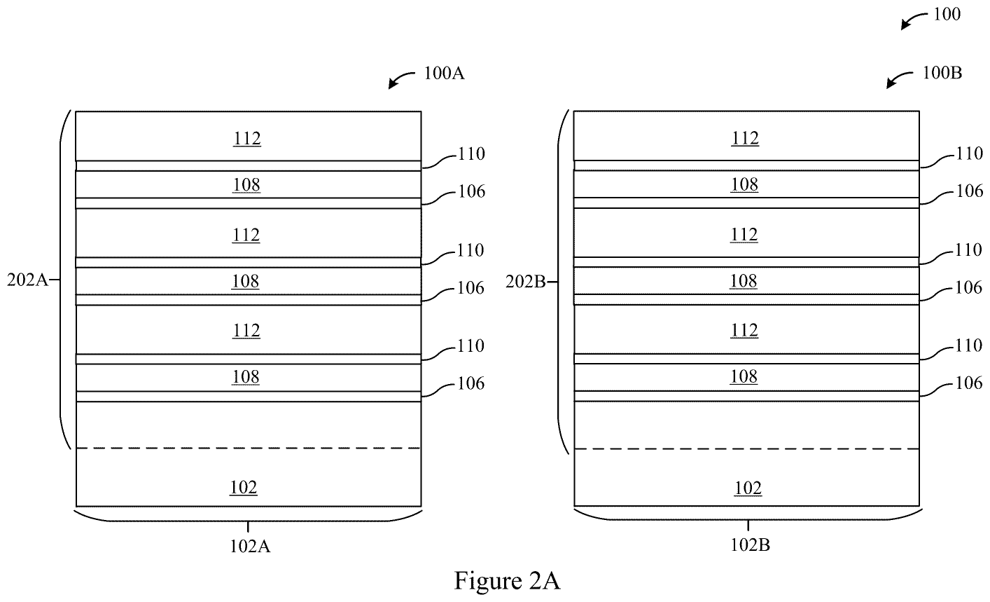

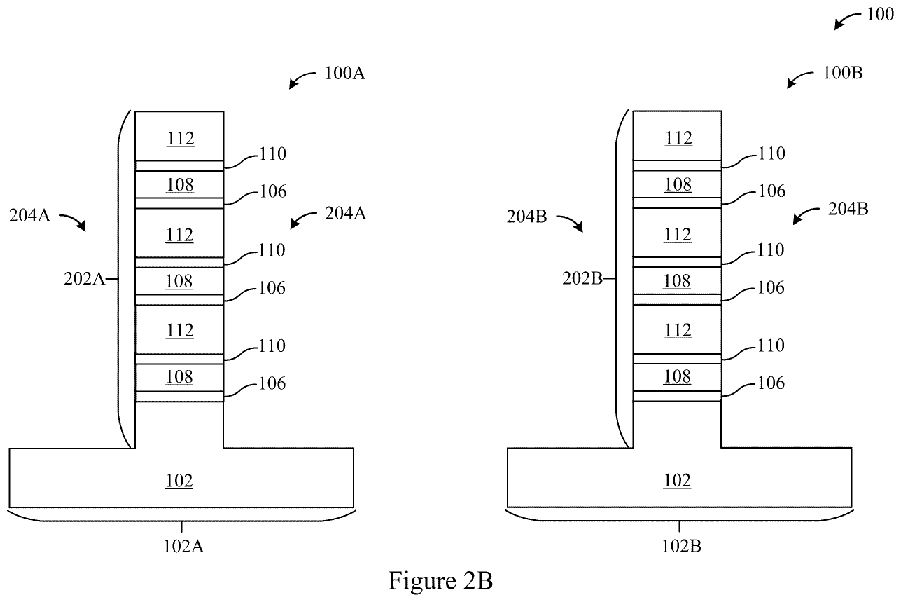

In FIGS. 2A and 2B, the stack 104 is patterned to form a first semiconductor structure 202A in the first region 102A and a second semiconductor structure 202B in the second region 102B. The first semiconductor structure 202A and the second semiconductor structure 202B retain the layered composition of the original stack 104, including the alternating layers 106, 108, 110, and 112. In some embodiments, the patterning process forms trenches 204A in the first region 102A and trenches 204B in the second region 102B, such that the first semiconductor structure 202A is interposed between adjacent trenches 204A and the second semiconductor structure 202B is interposed between adjacent trenches 204B.

In various embodiments, the patterning process to form the semiconductor structures 202A and 202B may involve photolithography followed by one or more etching steps. For example, a photoresist layer may be applied over the stack 104, exposed to a pattern of light, and developed to form a mask. An anisotropic etching process, such as reactive ion etching (RIE), may then be used to transfer the pattern from the mask to the underlying stack 104 and partially into the substrate 102.

The resulting semiconductor structures 202A and 202B may take the form of strips, fins, or nanosheets, depending on their dimensions and the specific device architecture being implemented. In one or more embodiments, the width of these structures may be in the nanometer range, enabling the fabrication of highly scaled semiconductor devices. By creating semiconductor structures 202A and 202B with preserved layer stacks, this process sets the stage for the formation of multiple transistor channels in a vertical arrangement. This approach allows for increased device density and improved electrostatic control in the final device structure.

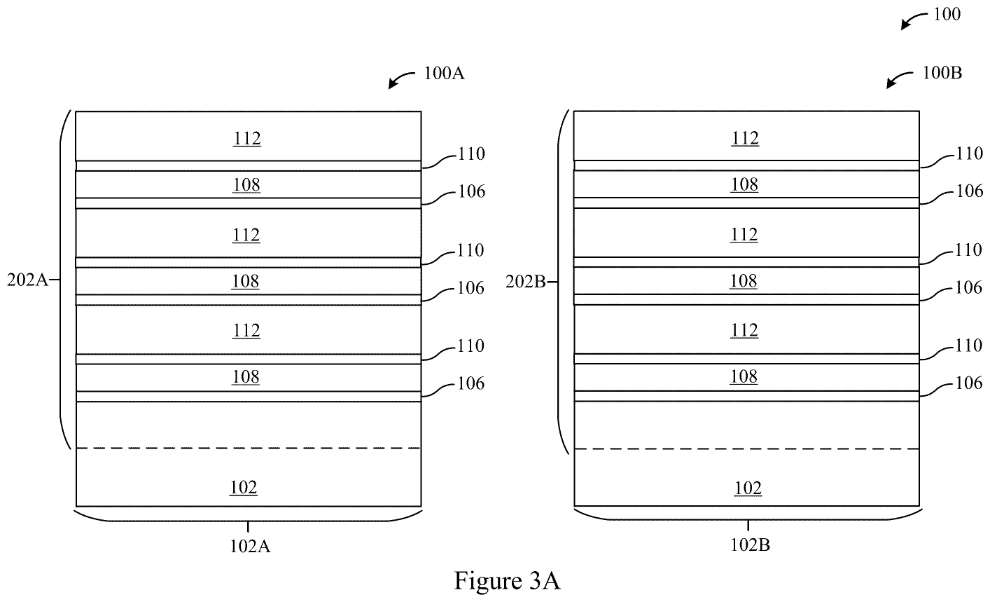

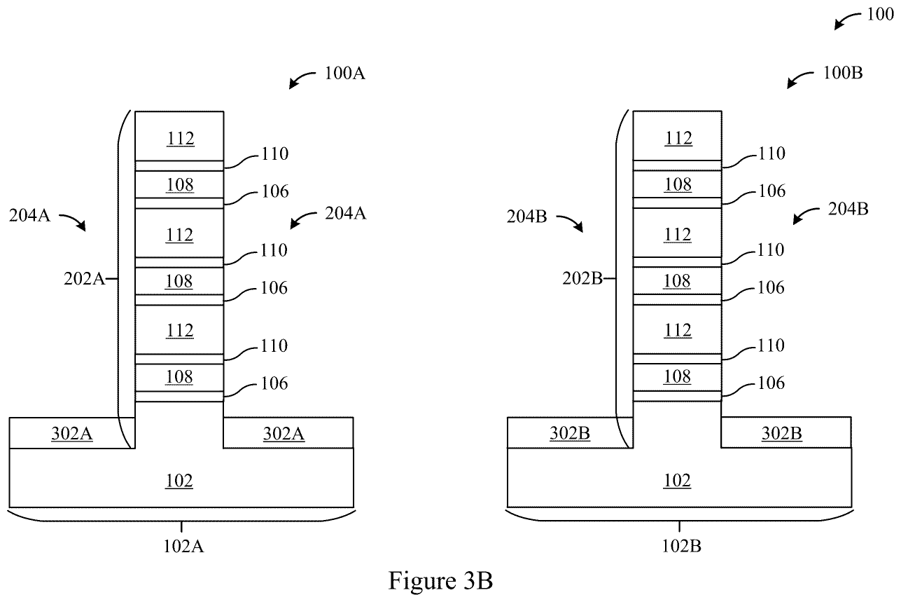

In FIGS. 3A and 3B, isolation regions 302A and 302B are formed within the trenches 204A and 204B, respectively. In some embodiments, the isolation regions 302A and 302B extend from the substrate 102 up to a level that partially exposes the vertical sides of the semiconductor structures 202A and 202B.

In some embodiments, the isolation regions 302A and 302B may comprise different dielectric materials. In such embodiments, the isolation regions 302A and 302B may be formed through a multi-step process. Initially, a first dielectric material may be deposited to fill the trenches 204A in the first region 102A and a second dielectric material different from the first dielectric material may be deposited to fill the trenches 204B in the second region 102B.

The deposition may be performed using techniques such as CVD, high-density plasma CVD (HDP-CVD), spin-on process, a combination thereof, or the like. Following the deposition, a planarization process, such as chemical-mechanical polishing (CMP), may be employed to substantially level a top surface of the first dielectric material with a top surface of the first semiconductor structure 202A and a top surface of the second dielectric material with a top surface of the second semiconductor structure 202B within process variations of planarization process.

In some embodiments, each of the first dielectric material and the second dielectric material may be selected based on its dielectric properties, thermal stability, and compatibility with subsequent processing steps. For example, silicon dioxide (SiO₂), silicon nitride (Si₃N₄), or low-k dielectric materials may be employed, depending on the specific requirements of the semiconductor device 100.

Subsequently, a first etch process may be utilized to recess the first dielectric material, creating the isolation regions 302A that partially expose the vertical sides of the semiconductor structure 202A and a second etch process different from the first etch process may be utilized to recess the second dielectric material, creating the isolation regions 302B that partially expose the vertical sides of the semiconductor structure 202B. In various embodiments, the extent of this recess may be controlled to optimize the performance of the semiconductor device 100. The exposed portions of the semiconductor structures 202A and 202B above the isolation regions 302A and 302B may serve as active regions for subsequent device formation.

In other embodiments, the isolation regions 302A and 302B may comprise a same dielectric material. In such embodiments, instead of two different dielectric materials, a single dielectric material may be deposited in trenches 204A and 204B. Subsequently, a single etch process may be utilized to recess the deposited dielectric material, creating the isolation regions 302A and 302B.

The isolation regions 302A and 302B may serve multiple functions in the semiconductor device 100. The isolation regions 302A and 302B may provide electrical isolation between adjacent semiconductor structures 202A and 202B, preventing unwanted current leakage. Additionally, the isolation regions 302A and 302B may offer structural support to the semiconductor structures 202A and 202B, enhancing the overall stability of the semiconductor device 100.

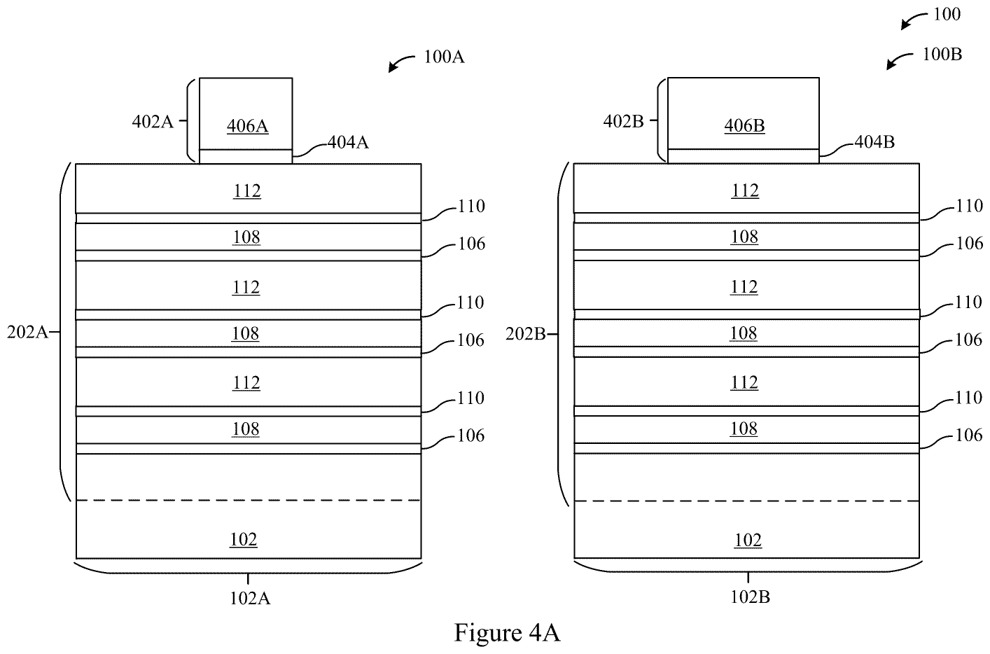

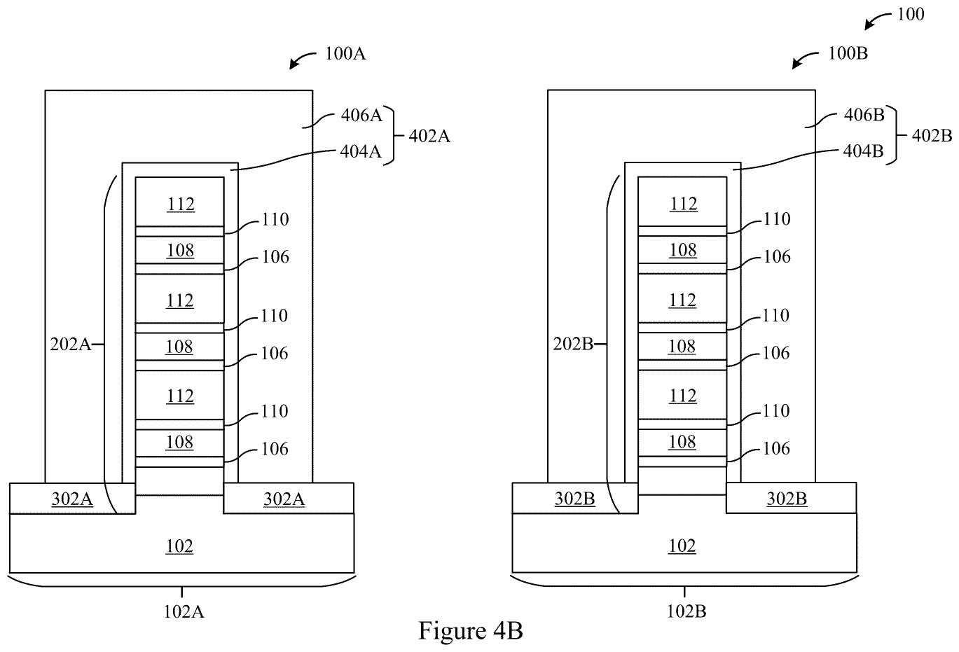

In FIGS. 4A and 4B, a first sacrificial gate 402A is formed over the first semiconductor structure 202A in the first region 102A, and a second sacrificial gate 402B is formed over the second semiconductor structure 202B in the second region 102B. The first sacrificial gate 402A comprises a first sacrificial gate dielectric layer 404A and a first sacrificial gate electrode layer 406A. The second sacrificial gate 402B comprises a second sacrificial gate dielectric layer 404B and a second sacrificial gate electrode layer 406B. In some embodiments, the first sacrificial gate 402A and the second sacrificial gate 402B may have a same or different length. In the illustrated embodiment, a first length of the first sacrificial gate 402A is less than a second length of the second sacrificial gate 402B.

In some embodiments, the sacrificial gates 402A and 402B may comprise different sacrificial gate dielectric materials and different sacrificial gate electrode materials. In such embodiments, the sacrificial gates 402A and 402B may be formed through a multi-step process. Initially, a first sacrificial gate dielectric material may be blanket deposited over the first region 102A and a second sacrificial gate dielectric material different from the first sacrificial gate dielectric material may be blanket deposited over the second region 102B. Each of the first sacrificial gate dielectric material and the second sacrificial gate dielectric material may be silicon oxide, a high-k dielectric such as hafnium oxide (HfO₂), zirconium oxide (ZrO₂), or another suitable dielectric material. The deposition may be performed using techniques such as ALD, CVD, a combination thereof, or the like.

After depositing the first sacrificial gate dielectric material and the second sacrificial gate dielectric material, a first sacrificial gate electrode material may be blanket deposited over the first sacrificial gate dielectric material in the first region 102A and a second sacrificial gate electrode material may be blanket deposited over the second sacrificial gate dielectric material in the second region 102B. In some embodiments, each of the first sacrificial gate electrode material and the second sacrificial gate electrode material may be polysilicon, though other materials such as amorphous silicon, or certain metals may also be used. The deposition of the first sacrificial gate electrode material and the second sacrificial gate electrode material may be accomplished through techniques like CVD, physical vapor deposition (PVD), a combination thereof, or the like.

After the deposition of the first sacrificial gate electrode material and the second sacrificial gate electrode material, a first patterning process may be employed to define a shape and dimensions of the first sacrificial gate 402A and a second patterning process may be employed to define a shape and dimensions of the second sacrificial gate 402B. The first pattering process may involve photolithography followed by etching steps. For example, a first photoresist layer may be applied over the first sacrificial gate electrode material in the first region 102A, exposed to a pattern of light, and developed to form a first mask. A first anisotropic etching process, such as reactive ion etching (RIE), may then be used to transfer the pattern from the first mask to the underlying first sacrificial gate electrode material and first sacrificial gate dielectric material. The second pattering process may involve photolithography followed by etching steps. For example, a second photoresist layer may be applied over the second sacrificial gate electrode material in the second region 102B, exposed to a pattern of light, and developed to form a second mask. A second anisotropic etching process, such as reactive ion etching (RIE), may then be used to transfer the pattern from the second mask to the underlying second sacrificial gate electrode material and second sacrificial gate dielectric material.

In other embodiments, the sacrificial gates 402A and 402B may comprise a same sacrificial gate dielectric material and a same sacrificial gate electrode material. In such embodiments, instead of two different sacrificial gate dielectric materials, a single sacrificial gate dielectric material may be deposited in regions 102A and 10B. Furthermore, instead of two different sacrificial gate electrode materials, a single sacrificial gate electrode material may be deposited in regions 102A and 10B. Subsequently, a single patterning process may be employed to define shapes and dimensions of the first sacrificial gate 402A and the second sacrificial gate 402A.

In one or more embodiments, the lengths of the sacrificial gates 402A and 402B may be controlled to define the eventual gate lengths of the GAA devices 100A and 100B being formed. The sacrificial gates 402A and 402B may serve as placeholders, allowing for the formation of other device components before the final gate structures are created. The sacrificial gates 402A and 402B enable the use of a “gate-last” or “replacement gate” process, which allows for better control over the final gate stack composition and properties.

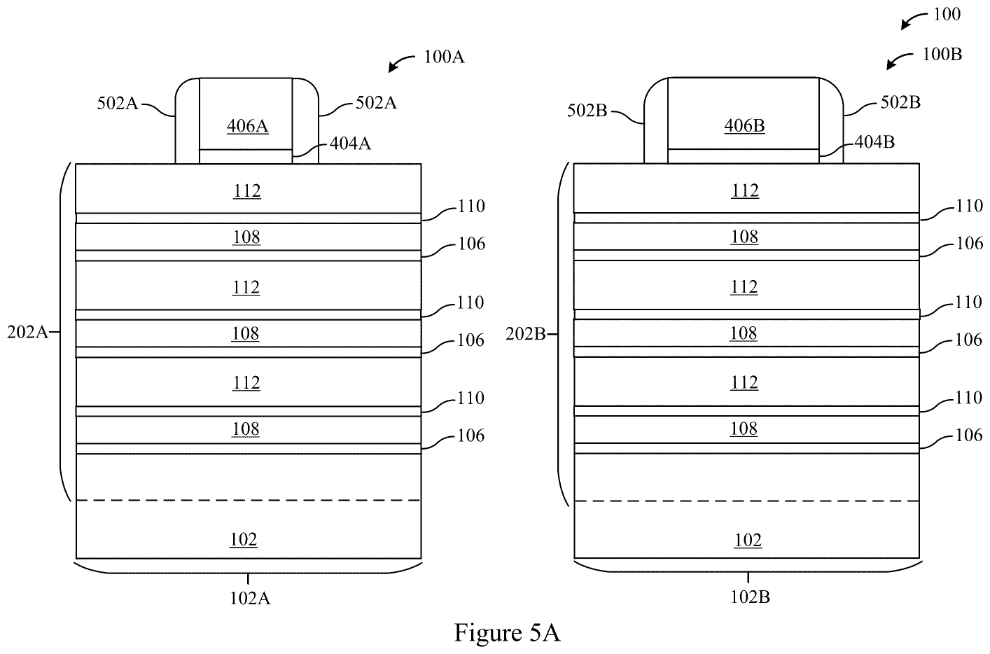

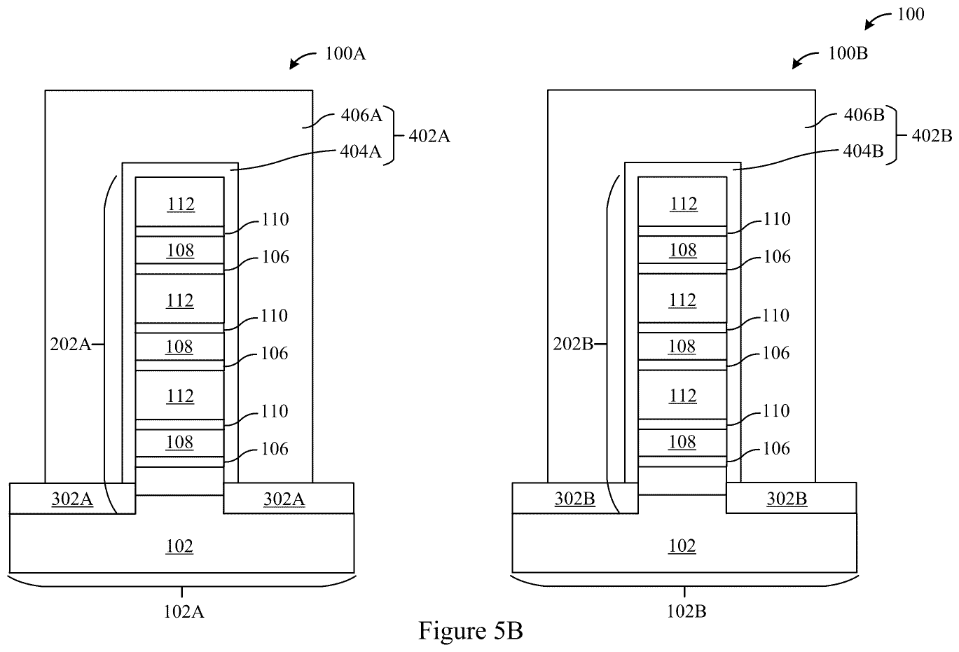

In FIGS. 5A and 5B, first gate spacers 502A are formed on the sidewalls of the first sacrificial gate 402A in the first region 102A and second gate spacers 502B are formed on the sidewalls of the second sacrificial gate 402B in the second region 102B. The width of the gate spacers 502A and 502B may be controlled to define the separation between the gate region and the subsequently formed source/drain regions.

In various embodiments, the formation of the gate spacers 502A and 502B may involve different materials and processes, depending on the specific requirements of the semiconductor device 100. In some embodiments, the gate spacers 502A and 502B may comprise the same material and may be formed through a single deposition and etch process. For example, a uniform layer of a spacer material, such as silicon oxide, silicon nitride, silicon oxynitride (SiON), or the like may be deposited over the sacrificial gates 402A and 402B using CVD, plasma-enhanced CVD (PECVD), ALD, a combination thereof, or the like. An anisotropic etching process, such as reactive ion etching (RIE), may then be employed to remove the spacer material from horizontal surfaces while leaving it intact on the vertical sidewalls of the sacrificial gates 402A and 402B, thus forming the gate spacers 502A and 502B.

In other embodiments, the gate spacers 502A and 502B may comprise different materials and may be formed through separate and different deposition and etch processes. For instance, the gate spacers 502A in the first region 102A may be formed using a first material, such as silicon nitride, while the gate spacers 502B in the second region 102B may be formed using a second material, such as silicon oxynitride. This approach allows for optimization of spacer properties for different types of devices (e.g., NMOS and PMOS transistors) within the same semiconductor device 100.

In yet other embodiments, the gate spacers 502A and 502B may be formed as multi-layer structures. For example, a thin layer of silicon oxide may be deposited first, followed by a layer of silicon nitride. This multi-layer approach can provide enhanced etch selectivity and better control over subsequent processing steps.

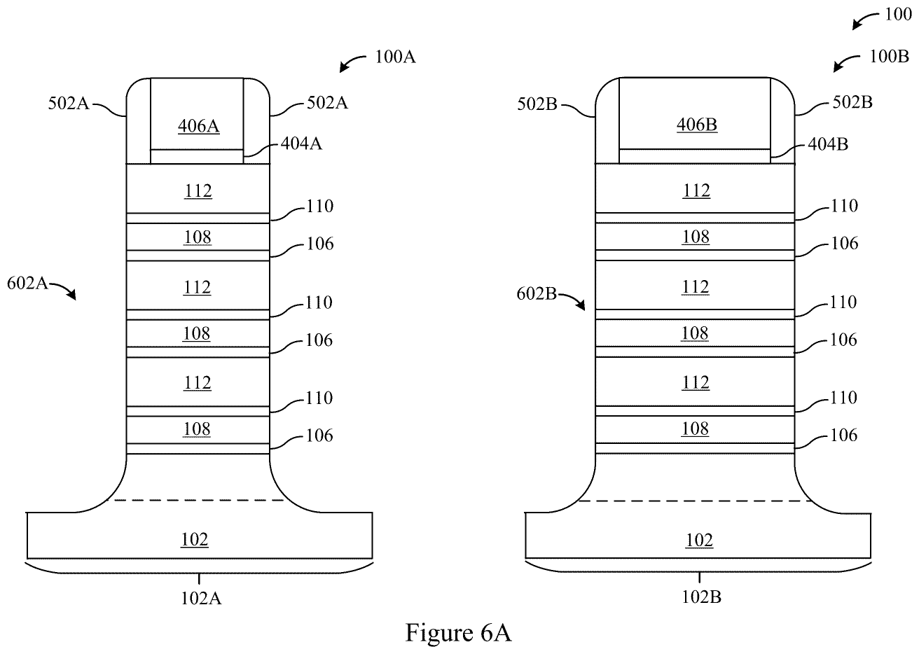

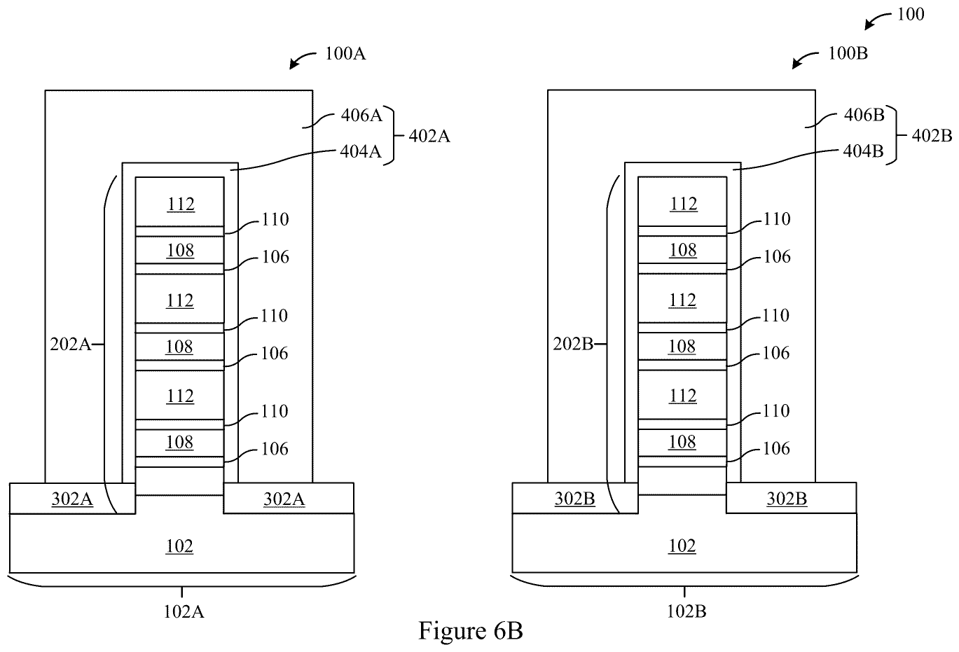

In FIGS. 6A and 6B, first recesses 602A are formed in the first semiconductor structure 202A adjacent to the first sacrificial gate 402A in the first region 102A and second recesses 602B are formed in the second semiconductor structure 202B adjacent to the second sacrificial gate 402B in the second region 102B. The recesses 602A and 602B create space for the subsequent formation of source/drain regions.

In various embodiments, the formation of the recesses 602A and 602B may involve a controlled etching process. This etching process may be selective, preferentially removing certain layers of the semiconductor structures 202A and 202B while leaving others relatively intact. The etching process to form the recesses 602A and 602B may be performed using techniques such as reactive ion etching (RIE), plasma etching, wet etching, a combination thereof, or the like. The choice of etching technique and etchant chemistry may be determined based on the desired etch selectivity between the different semiconductor materials in the stack. The sacrificial gates 402A and 402B, along with their respective gate spacers 502A and 502B, serve as a mask during the etching process.

In some embodiments, the recesses 602A and 602B may be formed through a single etch process. In other embodiments, the recesses 602A and 602B may be formed through separate and different etch processes. In some embodiments, the width, depth and profile of the recesses 602A and 602B may be controlled as they influence the performance of the semiconductor device 100. In some embodiments, the recesses 602A and 602B may have a same width, depth and/or profile. In other embodiments, the recesses 602A and 602B may have different widths, depths and/or profiles.

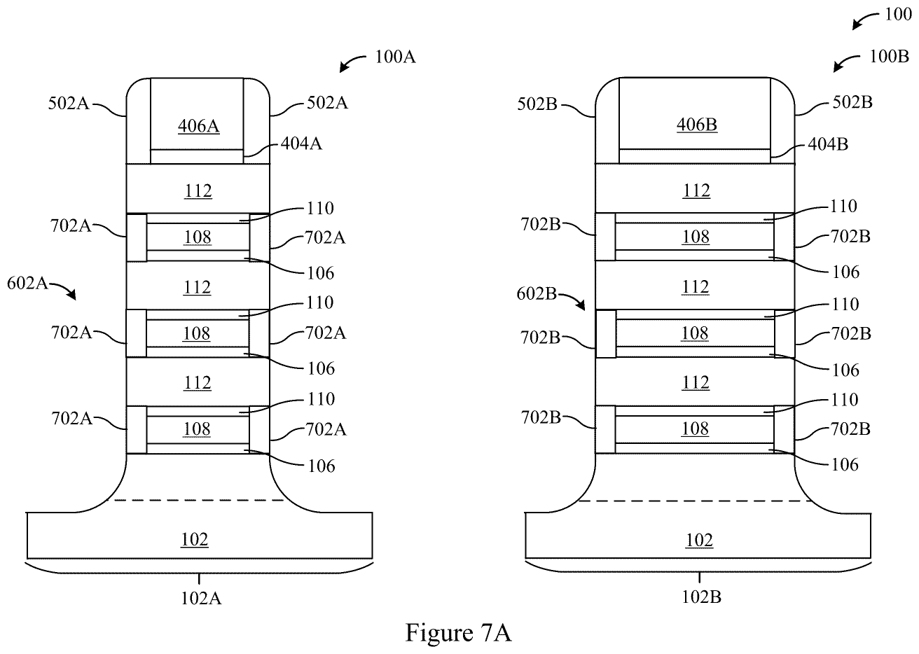

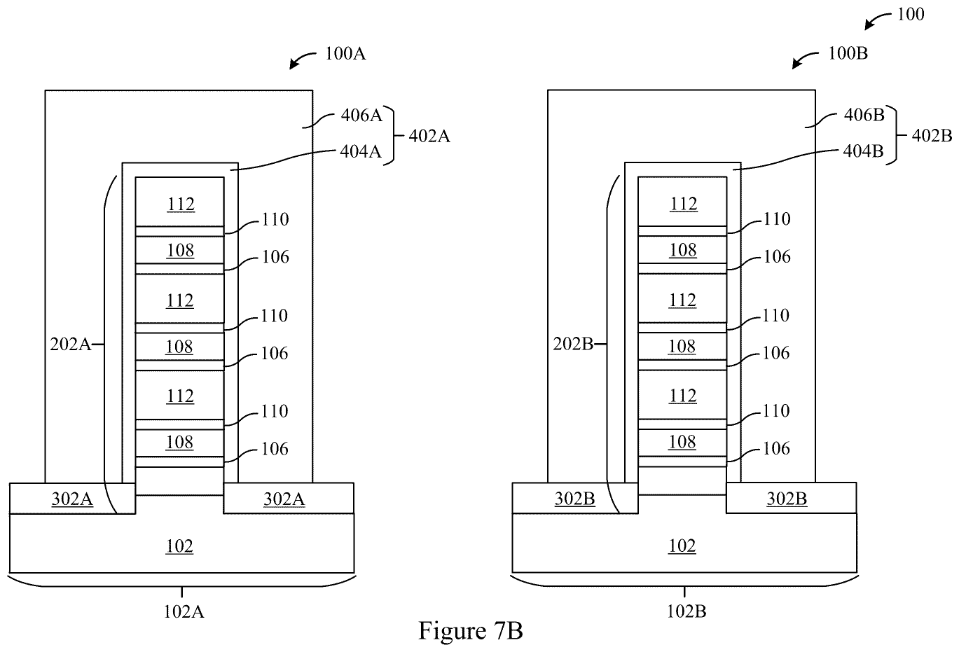

In FIGS. 7A and 7B, first inner spacers 702A are formed in the sidewalls of the first recesses 602A in the first region 102A and second inner spacers 702B are formed in the sidewalls of the second recesses 602B in the second region 102B. The inner spacers 702A and 702B may serve multiple functions. For example, they may provide electrical isolation between the gate and source/drain regions, help to reduce short-channel effects by effectively increasing the gate length at the edges of the channel, and contribute to strain engineering in the channel region.

In various embodiments, the formation of the inner spacers 702A and 702B may involve a multi-step process. Initially, the sidewalls of the first layer 106, second layer 108, and third layer 110 within the recesses 602A and 602B may be selectively etched to create recesses. This selective etching process may be designed to preferentially remove certain materials (such as the layers 106-110) while leaving other materials (such as the layers 112) relatively intact.

In some embodiments, the inner spacers 702A and 702B may comprise the same material and may be formed through a single deposition and etch process. In such embodiments, following the selective etching, a dielectric material may be deposited to fill the recesses. The deposition may be performed using techniques such as CVD, ALD, a combination thereof, or the like. The dielectric material used for the inner spacers 702A and 702B may be selected based on its etch selectivity relative to the semiconductor materials and its electrical insulating properties. For example, the dielectric material may comprise silicon oxide, silicon nitride, silicon oxynitride, or the like. After deposition, an anisotropic etching process may be employed to remove excess dielectric material overfilling the recesses, thus forming the inner spacers 702A and 702B. In other embodiments, the inner spacers 702A and 702B may comprise different materials and may be formed through separate and different deposition and etch processes.

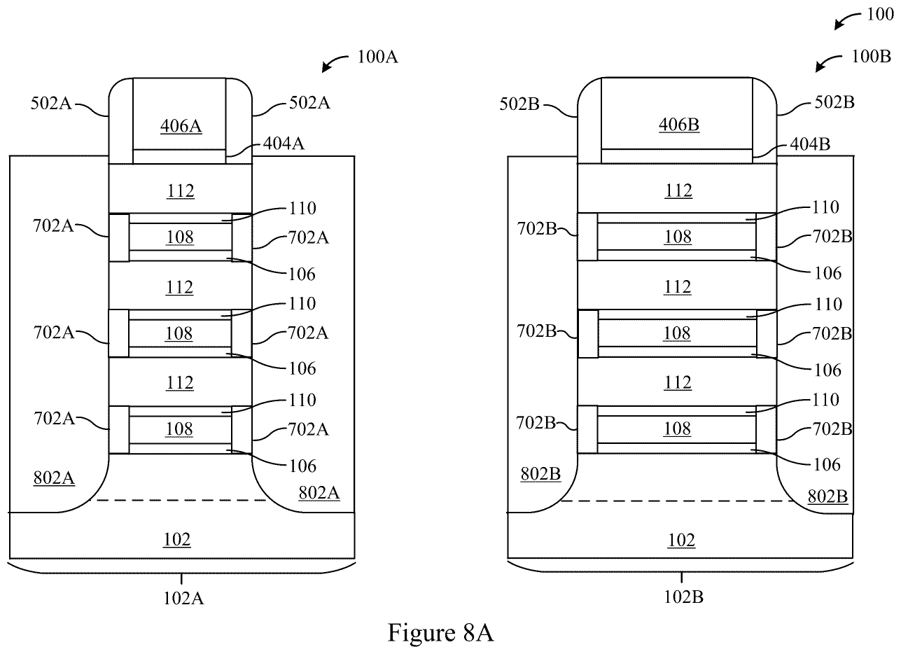

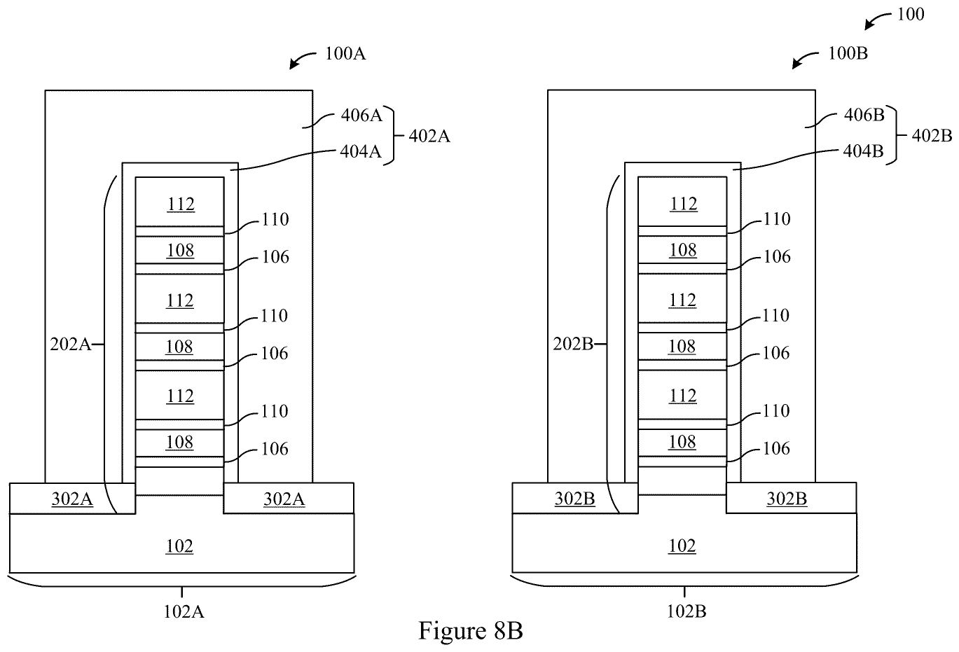

In FIGS. 8A and 8B, first epitaxial regions 802A are formed adjacent to the first sacrificial gate 402A in the first region 102A and second epitaxial regions 802B are formed adjacent to the second sacrificial gate 402B in the second region 102B. The epitaxial regions 802A and 802B are formed within the recesses 602A and 602B (see FIGS. 7A and 7B), respectively, and extend outward from the semiconductor structures 202A and 202B.

In various embodiments, the formation of the epitaxial regions 802A and 802B may involve an epitaxial growth process. This process may be carried out using techniques such as CVD, molecular beam epitaxy (MBE), vapor phase epitaxy (VPE), a combination thereof, or the like. The epitaxial growth may be selective, occurring only on exposed semiconductor surfaces and not on dielectric surfaces such as the gate spacers and inner spacers.

The material composition of the epitaxial regions 802A and 802B may be chosen based on the desired electrical characteristics of the semiconductor device 100. In some embodiments, the epitaxial regions 802A and 802B may comprise a same material. In other embodiments, the epitaxial regions 802A and 802B may comprise different materials. For example, in an embodiment where the GAA device 100A or 100B is intended to be an NMOS device, the respective epitaxial regions may be formed of a material that induces tensile strain in the channel region, such as phosphorus doped silicon (Si: P). In an embodiment where the GAA device 100A or 100B is intended to be a PMOS device, the respective epitaxial regions may be formed of a material that induces compressive strain, such as boron doped silicon germanium (SiGe: B) having a germanium content greater than or equal to 40 at %.

In one or more embodiments, the epitaxial growth process may be followed by in-situ or ex-situ doping process to introduce specific impurities into the epitaxial regions 802A and 802B and form source/drain regions. The doping process may be performed using techniques such as ion implantation, plasma doping, gas-phase doping, a combination thereof, or the like. The type and concentration of dopants may be selected to achieve desired electrical properties for the source/drain regions of the semiconductor device 100.

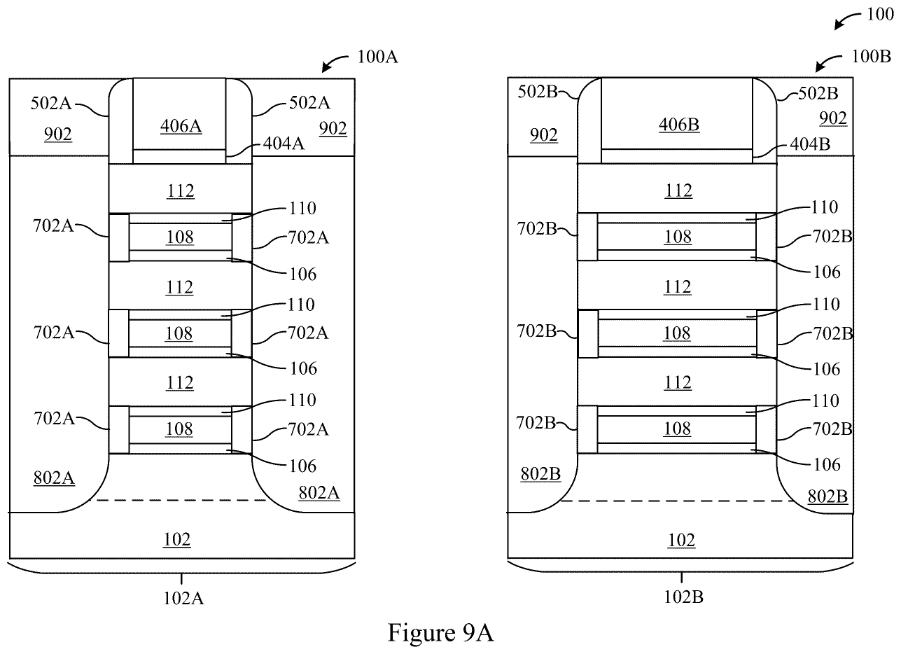

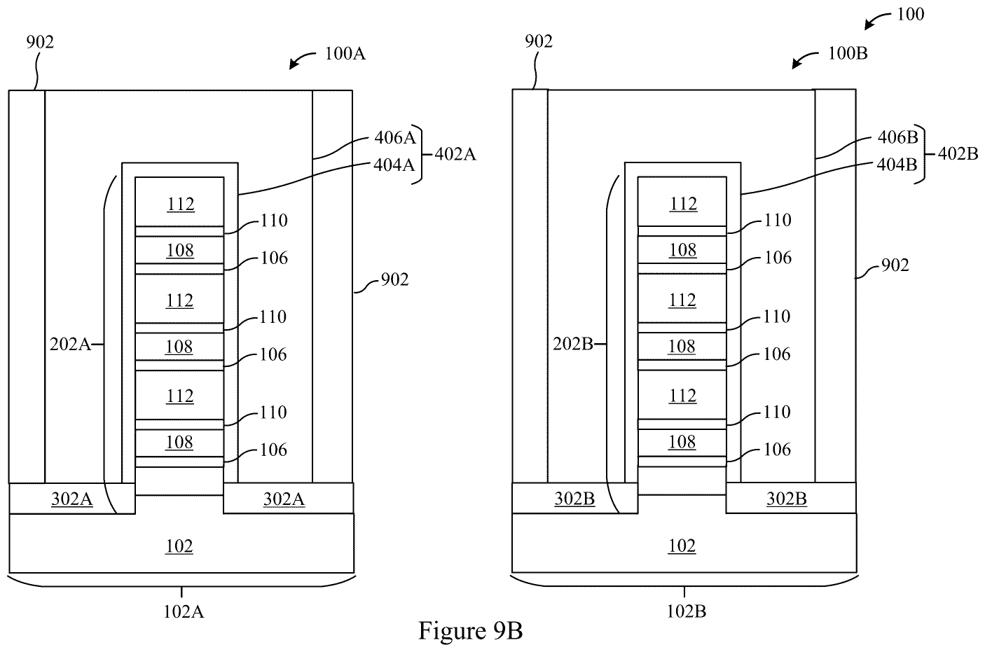

In FIGS. 9A and 9B, an interlayer dielectric (ILD) layer 902 is formed over the structure of FIGS. 8A and 8B. In various embodiments, the formation of the ILD layer 902 may involve a multi-step process. Initially, a dielectric material may be deposited over the entire structure using techniques such as CVD, PECVD, HDP-CVD, a spin-on process, a combination thereof, or the like. The dielectric material may be silicon oxide, silicon nitride, a low-k dielectric material, a combination thereof, or the like.

Following the deposition, a planarization process may be performed to achieve a flat surface across the ILD layer 902. This planarization may be accomplished through CMP or a combination of etch-back and CMP processes. The planarization process may substantially level a top surface of the ILD layer 902 with top surfaces of the sacrificial gates 402A and 402B within process variations of the planarization process.

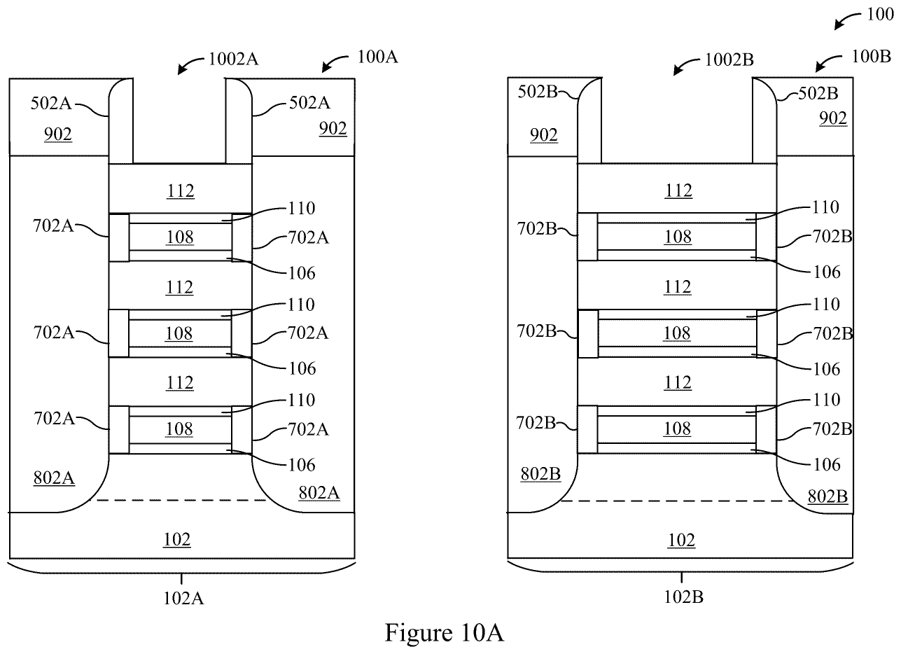

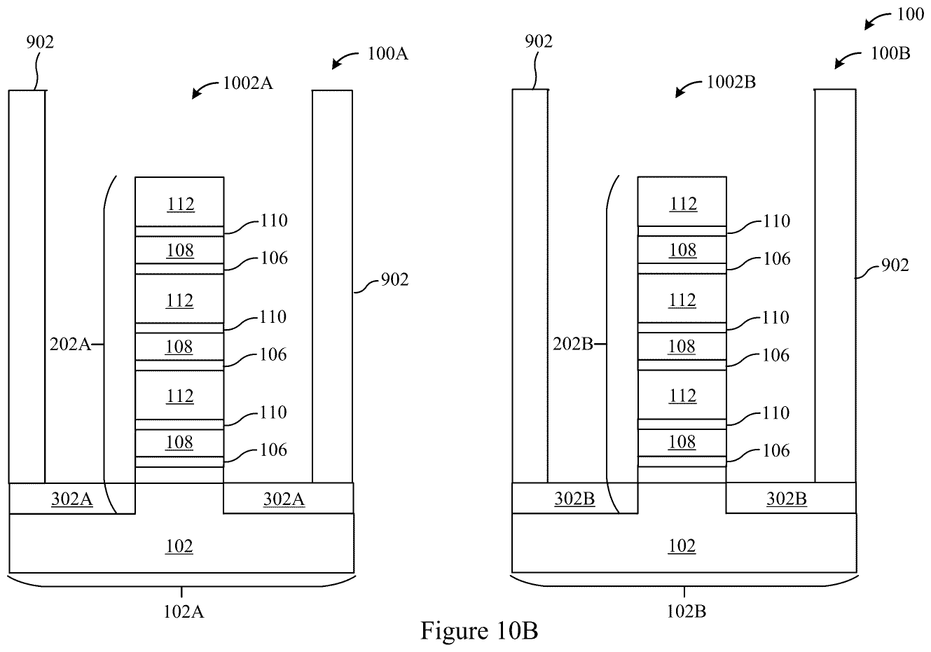

In FIGS. 10A and 10B, the first sacrificial gate 402A (see FIGS. 9A and 9B) is removed to form a first recess 1002A in the first region 102A and the second sacrificial gate 402B (see FIGS. 9A and 9B) is removed to form a second recess 1002B in the second region 102B.

In various embodiments, the removal of the sacrificial gates 402A and 402B to form the recesses 1002A and 1002B, respectively, may involve one or more selective etching processes. The one or more selective etching processes may be designed to remove the sacrificial gate electrode layers 406A and 406B and the sacrificial gate dielectric layers 404A and 404B while leaving the surrounding structures intact.

The one or more selective etching processes may be performed using techniques such as wet etching, dry etching, a combination thereof, or the like. For example, if the sacrificial gate electrode layers 406A and 406B are composed of polysilicon, they may be removed using a selective wet etch process with an etchant such as tetramethylammonium hydroxide (TMAH) or potassium hydroxide (KOH). The sacrificial gate dielectric layers 404A and 404B may then be removed using a different etchant that is selective to the respective dielectric materials used.

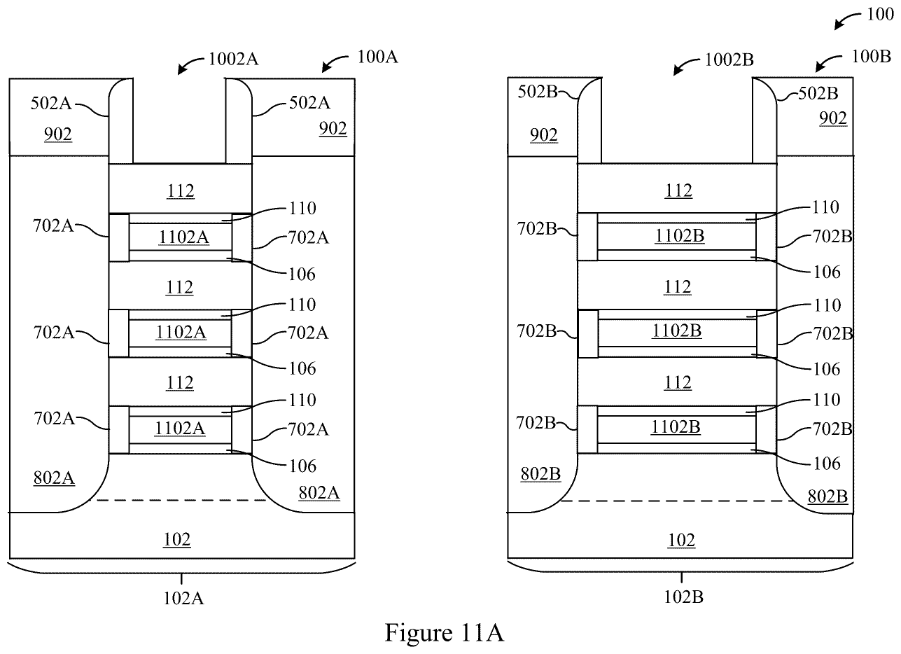

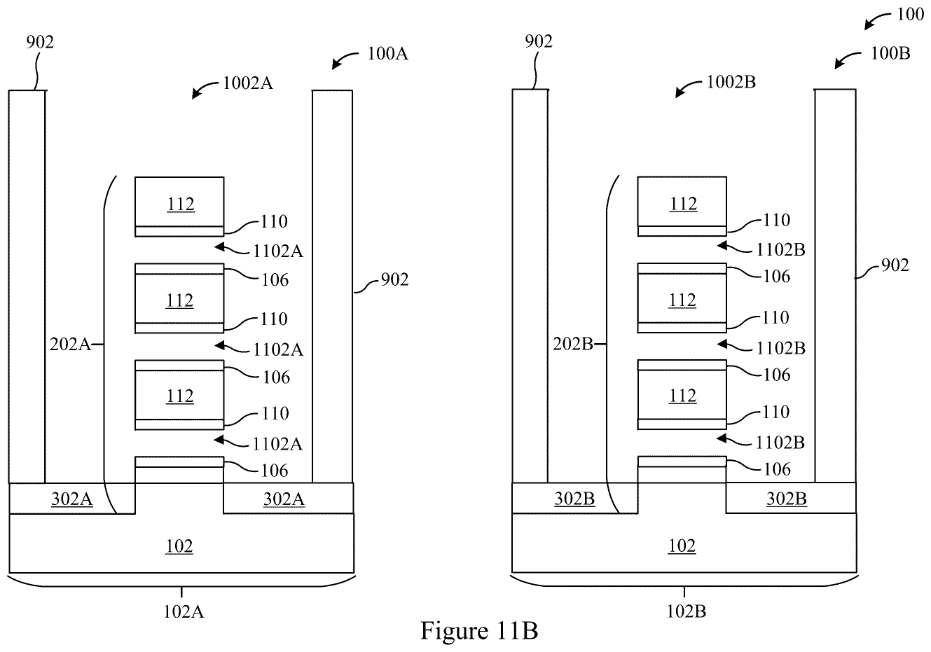

In FIGS. 11A and 11B, the layers 108 (see FIGS. 10A and 10B) are removed from the first semiconductor structure 202A to form first openings 1102A in the first region 102A and the layers 108 (see FIGS. 10A and 10B) are removed from the second semiconductor structure 202B to form second openings 1102B in the second region 102B.

In various embodiments, the formation of the openings 1102A and 1102B may involve one or more selective etching processes designed to remove specific layers within the semiconductor structures 202A and 202B. In an embodiment where the first layer 106 and third layer 110 comprise silicon germanium (SiGe) with a first germanium concentration, and the second layer 108 comprises SiGe with a second germanium concentration greater than the first germanium concentration, the etching process may be carried out by a first etch process followed by a second etch process different from the first etch process.

The first etch process may selectively remove a native oxide that may be formed on the layers 106-110 using a first etchant that preferentially attacks the native oxide. The first etchant may comprise a mixture of chemicals such as NH₃, HF, Ar, or N₂, and may be applied at a process pressure in a range from 10 mTorr to 2000 mTorr and a process temperature in a range from 0° C. to 80° C. The first etch process may be also referred to as a break-through etch process.

The second etch process may selectively remove the second layers 108 using a second etchant that preferentially attacks SiGe with the second germanium concentration. The second etchant may comprise a mixture of chemicals such as F₂, ClF₃, HF, Ar, or N₂, and may be applied at a process pressure in a range from 10 mTorr to 500 mTorr and a process temperature in a range from 0° C. to 55° C.

In one or more embodiments, thermal treatments may be performed between or after performing the first etch process and the second etch process. The thermal treatments may aid in removing any etch byproducts that may be left behind after performing the first etch process and/or the second etch process. The thermal treatments may be conducted in an atmosphere comprising Ar, N₂, or a mixture thereof, at a process pressure in a range from 1000 mTorr to 5000 mTorr and a process temperature in a range from 100° C. to 200° C.

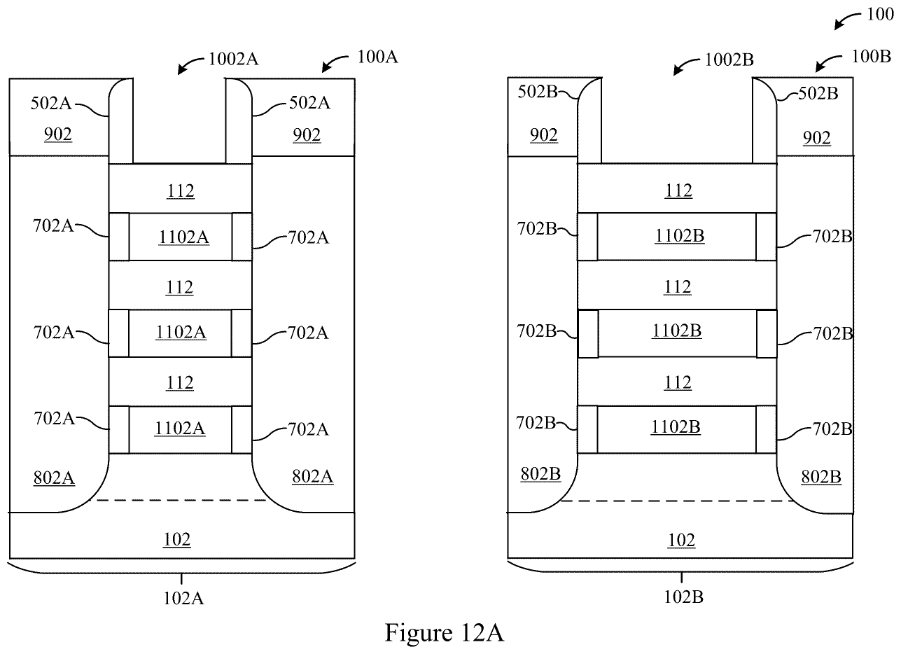

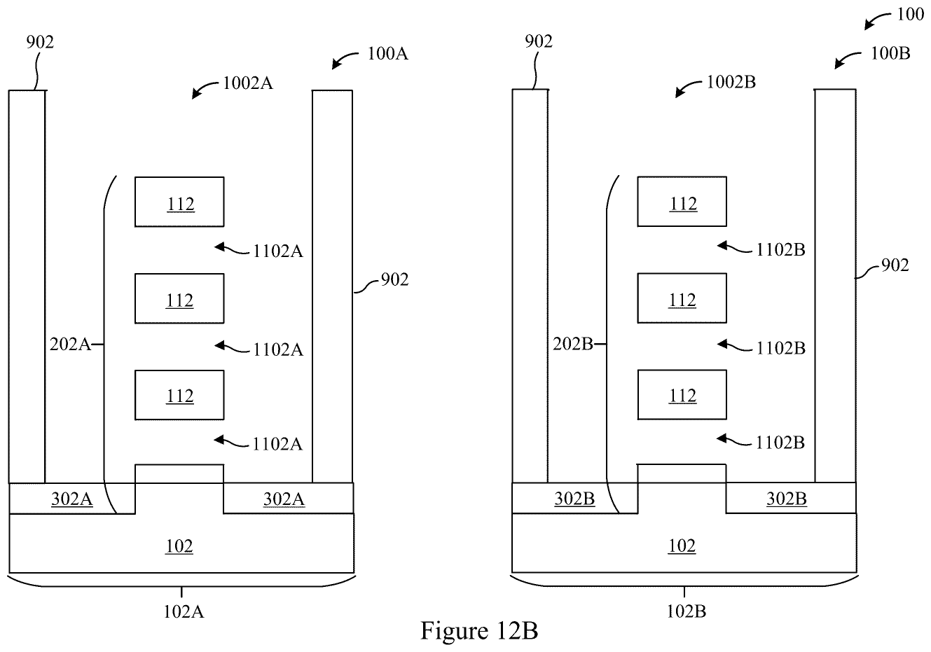

In FIGS. 12A and 12B, the layers 106 and 110 (see FIGS. 11A and 11B) are removed from the first semiconductor structure 202A to expand the first openings 1102A and the layers 106 and 110 (see FIGS. 11A and 11B) are removed from the second semiconductor structure 202B to expand the second openings 1102B. The expanded openings 1102A and 1102B separate the layers 112 (appearing as separate nanosheets or nanowires) that form channel regions of the GAA devices 100A and 100B. The expanded openings 1102A and 1102B further allow for the subsequent formation of gate structures that wrap around multiple channel regions, providing enhanced electrostatic control.

In various embodiments, the expansion of the openings 1102A and 1102B may involve a third etch process configured to selectively remove the layers 106 and 110 (see FIGS. 11A and 11B). In an embodiment where the layers 106 and 110 comprise silicon germanium (SiGe) having the first germanium concentration, the third etch process may use a third etchant that preferentially attacks SiGe with the first germanium concentration. The third etchant may comprise a mixture of chemicals such as F₂, NH₃, Ar, or N₂, and may be applied at a process pressure in a range from 10 mTorr to 250 mTorr and a process temperature in a range from 60° C. to 80° C.

In some embodiments, a thermal treatment may be performed after performing the third etch process. The thermal treatments may aid in removing any etch byproducts that may be left behind after performing the third etch process. The thermal treatments may be conducted in an atmosphere comprising Ar, N₂, or a mixture thereof, at a process pressure in a range from 1000 mTorr to 5000 mTorr and a process temperature in a range from 100° C. to 200° C.

In some embodiments, the first etch process, the second etch process and the thermal treatments described above with reference to FIGS. 11A and 11B, and the third etch process and the thermal treatment described above with reference to FIGS. 12A and 12B may be performed in a same process chamber. In other embodiments, some or all of these processes may be performed in separate process chambers.

The selective removal processes for forming the expanded openings 1102A and 1102B described above with reference to FIGS. 11A, 11B, 12A, and 12B, allow for controlling the dimensions and spacing of the channel regions. In particular, the selective removal processes may reduce or avoid non-uniform over-etching of the layers 112 such that channels of GAA devices with different channel lengths have a uniform channel thickness.

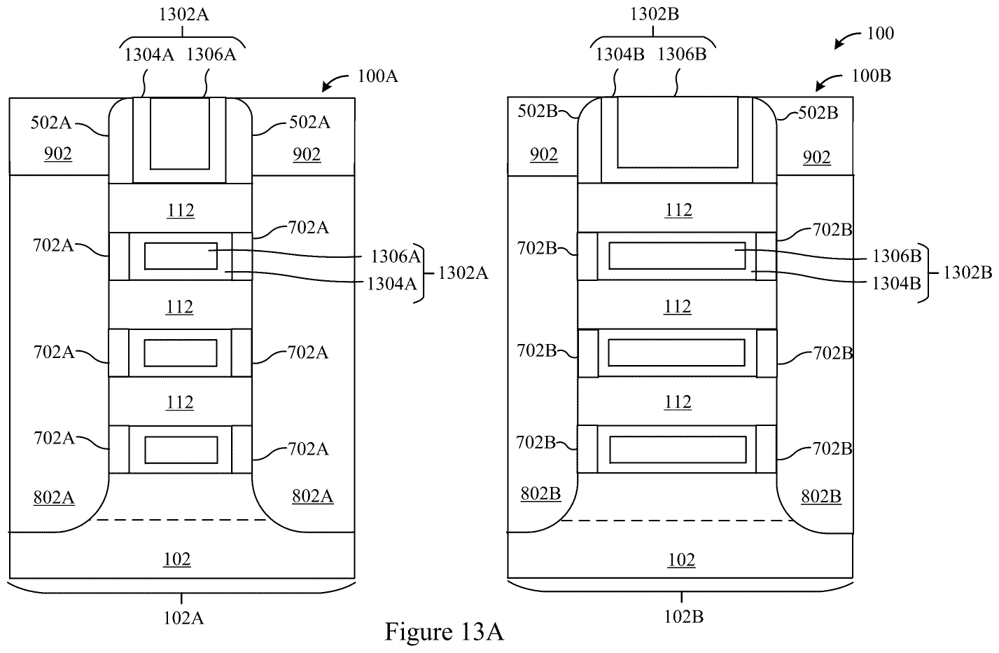

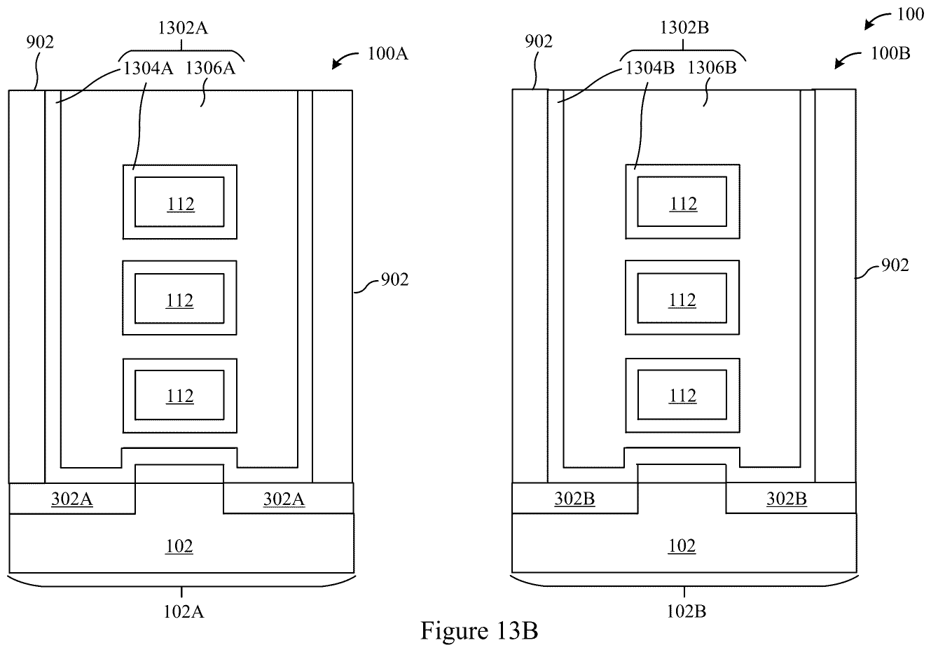

In FIGS. 13A and 13B, a first replacement gate 1302A is formed in the first recess 1002A and the first openings 1102A (see FIGS. 12A and 12B) and a second replacement gate 1302B is formed in the second recess 1002B and the second openings 1102B (see FIGS. 12A and 12B). The first replacement gate 1302A comprises a first replacement gate dielectric layer 1304A and a first replacement gate electrode layer 1306A. The second replacement gate 1302B comprises a second replacement gate dielectric layer 1304B and a second replacement gate electrode layer 1306B.

In some embodiments, the replacement gates 1302A and 1302B may comprise different replacement gate dielectric materials and different replacement gate electrode materials. In such embodiments, the replacement gates 1302A and 1302B may be formed through a multi-step process. Initially, a first replacement gate dielectric material may be deposited on exposed surfaces of the first recess 1002A and the first openings 1102A (see FIGS. 12A and 12B) and a second replacement gate dielectric material different from the first replacement gate dielectric material may be deposited on exposed surfaces of the second recess 1002B and the second openings 1102B (see FIGS. 12A and 12B). Each of the first replacement gate dielectric material and the second replacement gate dielectric material may be silicon oxide, a high-k dielectric such as hafnium oxide (HfO₂), zirconium oxide (ZrO₂), or another suitable dielectric material. The deposition may be performed using techniques such as ALD, CVD, a combination thereof, or the like.

After depositing the first replacement gate dielectric material and the second replacement gate dielectric material, the first recess 1002A and the first openings 1102A (see FIGS. 12A and 12B) are filled with a first replacement gate electrode material and the second recess 1002B and the second openings 1102B (see FIGS. 12A and 12B) are filled with a second replacement gate electrode material different from the first replacement gate electrode material. Each of the first replacement gate electrode material and the second replacement gate electrode material may comprise a metal or a stack of metals chosen for their work function and electrical properties, and may be formed using techniques such as physical vapor deposition PVD, CVD, ALD, a combination thereof, or the like. In some embodiments, each of the first replacement gate electrode material and the second replacement gate electrode material may comprise titanium (Ti), titanium nitride (TiN), tantalum (Ta), tantalum nitride (TaN), aluminum (Al), tungsten (W), Copper (Cu), a combination thereof, a multilayer thereof, or the like.

After depositing the first replacement gate electrode material and the second replacement gate electrode material, a planarization process such as CMP may be performed to remove excess replacement gate dielectric materials and excess replacement gate electrode materials such that a top surface of the first replacement gate 1302A and a top surface of the second replacement gate 1302B are substantially level with the top surface of the ILD layer 902 within process variations of the planarization process.

In other embodiments, the replacement gates 1302A and 1302B may comprise a same replacement gate dielectric material and a same replacement gate electrode material. In such embodiments, instead of two different replacement gate dielectric materials, a single replacement gate dielectric material may be deposited in regions 102A and 10B. Furthermore, instead of two different replacement gate electrode materials, a single replacement electrode material may be deposited in regions 102A and 10B.

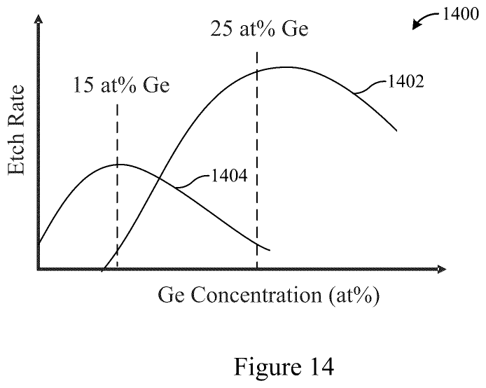

FIG. 14 illustrates a graph 1400 depicting the relationship between germanium concentration and etch rate of a SiGe material. The x-axis represents the germanium concentration in atomic percentage (at %), while the y-axis represents the etch rate of the SiGe material. The graph 1400 includes two curves, 1402 and 1404, representing different etch processes. In particular, the curve 1402 corresponds to the second etch process described above with reference to FIGS. 11A and 11B and the curve 1404 corresponds to the third etch process described above with reference to FIGS. 12A and 12B. The slopes and relative positions of these curves indicate the selectivity of each etch process to different germanium concentrations.

The curve 1402 shows a higher etch rate for germanium concentrations of about 25 at % compared to germanium concentrations of about 15 at %. This characteristic makes the second etch process suitable for selectively removing SiGe materials with high germanium content. The curve 1404 shows a higher etch rate for germanium concentrations of about 15 at % compared to germanium concentrations of about 25 at %. This characteristic makes the third etch process suitable for selectively removing SiGe materials with low germanium content.

In some embodiments, the etch rate difference between the two germanium concentrations for each etch process allows for precise control during the selective removal of SiGe materials. This selective etching capability may allow for improved process margins and reduced silicon loss across variable nanosheet lengths during the channel release process.

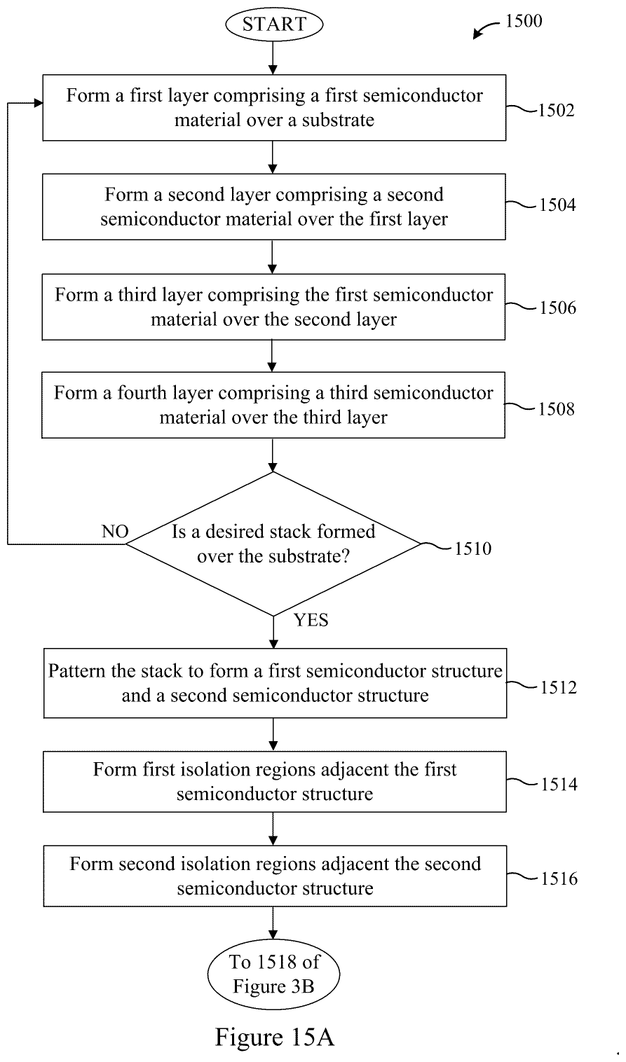

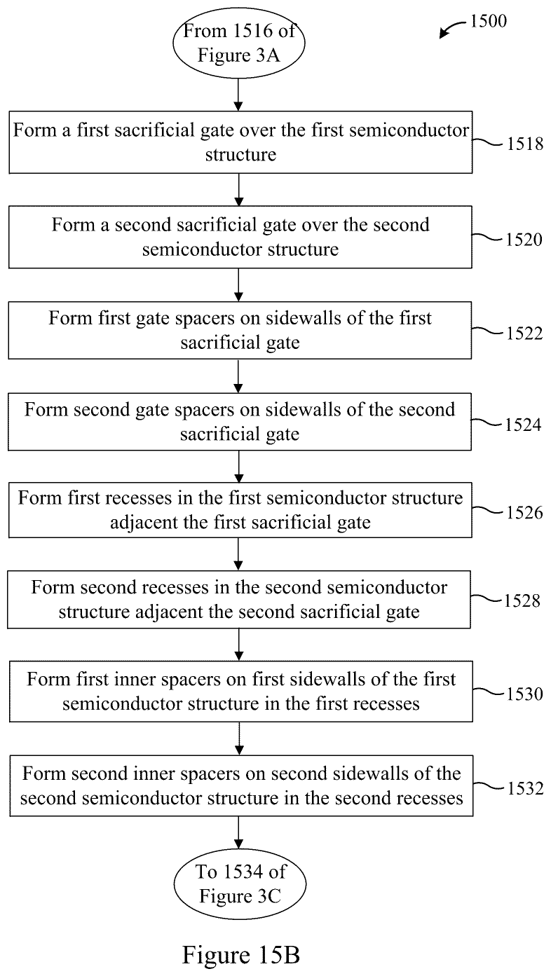

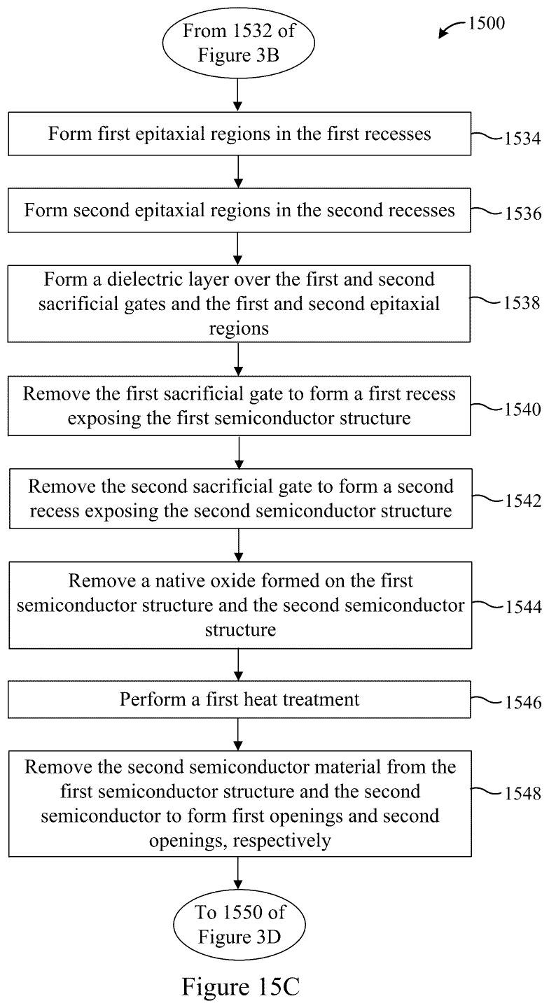

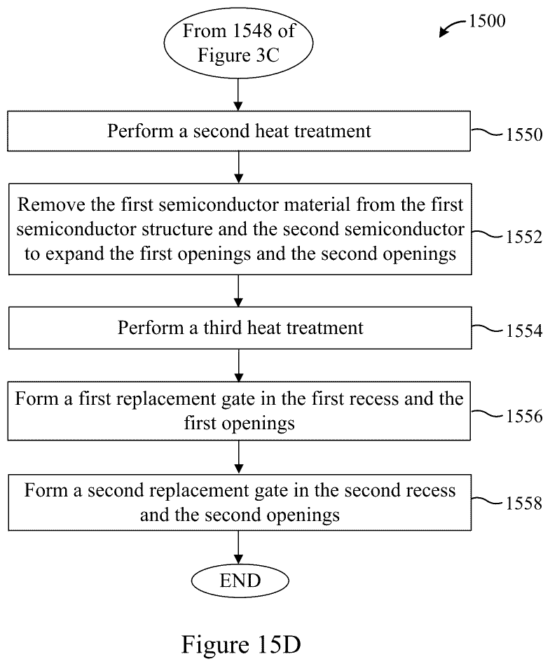

FIGS. 15A through 15D illustrate a flowchart of a method 1500 for fabricating a semiconductor device 100. The method 1500 includes various steps for forming a stack of semiconductor layers, patterning the stack, and creating gate structures. The progression of these steps corresponds to the structures described above with reference to FIGS. 1A-13A and 1B-13B.

In step 1502, a first layer 106 comprising a first semiconductor material is formed over a substrate 102, as described above with reference to FIGS. 1A and 1B. In step 1504, a second layer 108 comprising a second semiconductor material is formed over the first layer 106, as described above with reference to FIGS. 1A and 1B. In step 1506, a third layer 110 comprising the first semiconductor material is formed over the second layer 108, as described above with reference to FIGS. 1A and 1B. In step 1508, a fourth layer 112 comprising a third semiconductor material is formed over the third layer 110, as described above with reference to FIGS. 1A and 1B.

In step 1510, it is determined whether a desired stack is formed over the substrate 102. If the desired stack is not yet formed, the method 1500 returns to step 1502 to continue forming additional layers. If the desired stack is formed, the method proceeds to step 1512. This iterative process allows for the formation of a stack 104 with the desired number and composition of layers, as described above with reference to FIGS. 1A and 1B.

In step 1512, the stack 104 is patterned to form a first semiconductor structure 202A and a second semiconductor structure 202B, as described above with reference to FIGS. 2A and 2B. In step 1514, first isolation regions 302A are formed adjacent to the first semiconductor structure 202A, as described above with reference to FIGS. 3A and 3B. In step 1516, second isolation regions 302B are formed adjacent to the second semiconductor structure 202B, as described above with reference to FIGS. 3A and 3B.

In step 1518, a first sacrificial gate 402A is formed over the first semiconductor structure 202A, as described above with reference to FIGS. 4A and 4B. In step 1520, a second sacrificial gate 402B is formed over the second semiconductor structure 202B, as described above with reference to FIGS. 4A and 4B. In step 1522, first gate spacers 502A are formed on sidewalls of the first sacrificial gate 402A, as described above with reference to FIGS. 5A and 5B. In step 1524, second gate spacers 502B are formed on sidewalls of the second sacrificial gate 402B, as described above with reference to FIGS. 5A and 5B.

In step 1526, first recesses 602A are formed in the first semiconductor structure 202A adjacent to the first sacrificial gate 402A, as described above with reference to FIGS. 6A and 6B. In step 1528, second recesses 602B are formed in the second semiconductor structure 202B adjacent to the second sacrificial gate 402B, as described above with reference to FIGS. 6A and 6B. In step 1530, first inner spacers 702A are formed on first sidewalls of the first semiconductor structure 202A in the first recesses 602A, as described above with reference to FIGS. 7A and 7B. In step 1532, second inner spacers 702B are formed on second sidewalls of the second semiconductor structure 202B in the second recesses 602B, as described above with reference to FIGS. 7A and 7B.

In step 1534, first epitaxial regions 802A are formed in the first recesses 602A, as described above with reference to FIGS. 8A and 8B. In step 1536, second epitaxial regions 802B are formed in the second recesses 602B, as described above with reference to FIGS. 8A and 8B. In step 1538, a dielectric layer 902 is formed over the sacrificial gates 402A and 402B, and the epitaxial regions 802A and 802B, as described above with reference to FIGS. 9A and 8B. In step 1540, the first sacrificial gate 402A is removed to form a first recess 1002A exposing the first semiconductor structure 202A, as described above with reference to FIGS. 10A and 10B. In step 1542, the second sacrificial gate 402B is removed to form a second recess 1002B exposing the second semiconductor structure 202B, as described above with reference to FIGS. 10A and 10B.

In step 1544, a native oxide formed on the first semiconductor structure 202A and the second semiconductor structure 202B is removed, as described above with reference to FIGS. 11A and 11B. In step 1546, a first heat treatment is performed, as described above with reference to FIGS. 11A and 11B. In step 1548, the second semiconductor material is removed from the first semiconductor structure 202A and the second semiconductor structure 202B to form first openings 1102A and second openings 1102B, respectively, as described above with reference to FIGS. 11A and 11B. In step 1550, a second heat treatment is performed, as described above with reference to FIGS. 11A and 11B.

In step 1552, the first semiconductor material is removed from the first semiconductor structure 202A and the second semiconductor structure 202B to expand the first openings 1102A and the second openings 1102B, as described above with reference to FIGS. 12A and 12B. In step 1554, a third heat treatment is performed, as described above with reference to FIGS. 12A and 12B.

In step 1556, a first replacement gate 1302A is formed in the first recess 1002A and the first openings 1102A, as described above with reference to FIGS. 13A and 13B. In step 1558, a second replacement gate 1302B is formed in the second recess 1002B and the second openings 1102B, as described above with reference to FIGS. 13A and 13B.

In various embodiments, the steps of method 1500 may be performed in the order described above, or in a different order. Additionally, some steps may be performed simultaneously or in a partially overlapping manner. The specific order and combination of steps may be varied to achieve desired device characteristics or to accommodate different fabrication processes.

Example embodiments of the disclosure are described below. Other embodiments can also be understood from the entirety of the specification as well as the claims filed herein.

Example 1. A method including forming a stack of semiconductor layers over a substrate. The stack includes a first layer including a first semiconductor material over the substrate, a second layer including a second semiconductor material over the first layer, a third layer including the first semiconductor material over the second layer, and a fourth layer including a third semiconductor material over the third layer. The method further includes patterning the stack to form a semiconductor structure, forming a sacrificial gate over the semiconductor structure, forming epitaxial regions adjacent to the sacrificial gate, removing the sacrificial gate to form a recess, selectively removing the first layer and the third layer from the semiconductor structure through the recess to form an opening, selectively removing the second layer from the semiconductor structure through the recess to expand the opening, and forming a replacement gate in the recess and the opening.

Example 2. The method of example 1, where the first semiconductor material includes silicon germanium (SiGe) having a first germanium concentration, and the second semiconductor material includes SiGe having a second germanium concentration greater than the first germanium concentration.

Example 3. The method of example, where the first germanium concentration is in a range from 10 atomic percent to 15 atomic percent, and the second germanium concentration is in a range from 20 atomic percent to 25 atomic percent.

Example 4. The method of one of examples 1 to 3, where selectively removing the first layer and the third layer includes performing a first etch process.

Example 5. The method of example 4, where the first etch process uses an etchant including a mixture of F₂, ClF₃, HF, Ar, or N₂.

Example 6. The method of one of examples 4 and 5, where selectively removing the second layer includes a second etch process different from the first etch process.

Example 7. The method of example 6, where the first etch process uses an etchant including a mixture of F₂, NH₃, Ar, or N₂.

Example 8. A method including forming a stack of semiconductor layers on a substrate. The stack includes a first silicon germanium (SiGe) layer on the substrate. The first SiGe layer having a first germanium (Ge) concentration. The stack further includes a second SiGe layer on the first SiGe layer. The second SiGe layer having a second SiGe concentration greater than the first Ge concentration. The stack further includes a third SiGe layer on the second SiGe layer and a silicon (Si) layer on the third SiGe layer. The third SiGe layer having the first Ge concentration. The method further includes patterning the stack to form a semiconductor structure, forming a sacrificial gate over the semiconductor structure, forming epitaxial regions adjacent to the sacrificial gate, removing the sacrificial gate to form a recess, selectively etching the first SiGe layer and the third SiGe layer through the recess to form an opening, selectively etching the second SiGe layer through the recess to expand the opening, and forming a replacement gate in the recess and the opening.

Example 9. The method of example 8, further including, before selectively etching the first SiGe layer and the third SiGe layer: selectively etching a native oxide formed on the first SiGe layer and the third SiGe layer; and performing a thermal treatment.

Example 10. The method of example 9, where the thermal treatment is performed in an atmosphere including Ar, N₂, or a mixture of Ar and N₂.

Example 11. The method of one of examples 8 to 10, where the first SiGe layer and the third SiGe layer are selectively etched using an etchant including a mixture of F₂, ClF₃, HF, Ar, or N₂.

Example 12. The method of one of examples 8 to 11, where the second SiGe layer is selectively etched using an etchant including a mixture of F₂, NH₃, Ar, or N₂.

Example 13. The method of one of examples 8 to 12, further including, after selectively etching the first SiGe layer and the third SiGe layer, performing a thermal treatment.

Example 14. The method of one of examples 8 to 13, further including, after selectively etching the second SiGe layer, performing a thermal treatment.

Example 15. A method including forming a stack of semiconductor layers over a substrate. The stack includes a first layer including a first semiconductor material over the substrate, a second layer including a second semiconductor material over the first layer, a third layer including the first semiconductor material over the second layer, and a fourth layer including a third semiconductor material over the third layer. The method further includes patterning the stack to form a first semiconductor structure and a second semiconductor structure, forming a first sacrificial gate over the first semiconductor structure, and forming a second sacrificial gate over the second semiconductor structure. The first sacrificial gate has a first width. The second sacrificial gate has a second width greater than the first width. The method further includes forming first epitaxial regions adjacent to the first sacrificial gate, forming second epitaxial regions adjacent to the second sacrificial gate, removing the first sacrificial gate to form a first recess, removing the second sacrificial gate to form a second recess, selectively removing the first layer and the third layer from the first semiconductor structure through the first recess to form a first opening, selectively removing the first layer and the third layer from the second semiconductor structure through the second recess to form a second opening, selectively removing the second layer from the first semiconductor structure through the first recess to expand the first opening, selectively removing the second layer from the second semiconductor structure through the second recess to expand the second opening, forming a first replacement gate in the first recess and the first opening, and forming a second replacement gate in the second recess and the second opening.

Example 16. The method of example 15, where selectively removing the first layer and the third layer from the first semiconductor structure and selectively removing the first layer and the third layer from the second semiconductor structure includes performing a first etch process.

Example 17. The method of example 16, where the first etch process is performed at a process pressure in a range from 10 mTorr to 500 mTorr and a process temperature in a range from 0° C. to 55° C.

Example 18. The method of one of examples 16 and 17, where selectively removing the second layer from the first semiconductor structure and selectively removing the second layer from the second semiconductor structure includes performing a second etch process different from the first etch process.

Example 19. The method of example 18, where the second etch process is performed at a process pressure in a range from 10 mTorr to 250 mTorr and a process temperature in a range from 60° C. to 80° C.

Example 20. The method of one of examples 15 to 19, where the first semiconductor material includes silicon germanium (SiGe) having a first germanium concentration, the second semiconductor material includes SiGe having a second germanium concentration greater than the first germanium concentration, and the third semiconductor material includes silicon (Si).

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
forming a stack of semiconductor layers over a substrate, the stack comprising:
a first layer comprising a first semiconductor material over the substrate;
a second layer comprising a second semiconductor material over the first layer;
a third layer comprising the first semiconductor material over the second layer; and
a fourth layer comprising a third semiconductor material over the third layer;
patterning the stack to form a semiconductor structure;
forming a sacrificial gate over the semiconductor structure;
forming epitaxial regions adjacent to the sacrificial gate;
removing the sacrificial gate to form a recess;
selectively removing the first layer and the third layer from the semiconductor structure through the recess to form an opening;
selectively removing the second layer from the semiconductor structure through the recess to expand the opening; and
forming a replacement gate in the recess and the opening.

2. The method of claim 1, wherein the first semiconductor material comprises silicon germanium (SiGe) having a first germanium concentration, and the second semiconductor material comprises SiGe having a second germanium concentration greater than the first germanium concentration.

3. The method of claim 2, wherein the first germanium concentration is in a range from 10 atomic percent to 15 atomic percent, and the second germanium concentration is in a range from 20 atomic percent to 25 atomic percent.

4. The method of claim 1, wherein selectively removing the first layer and the third layer comprises performing a first etch process.

5. The method of claim 4, wherein the first etch process uses an etchant comprising a mixture of F₂, ClF₃, HF, Ar, or N₂.

6. The method of claim 4, wherein selectively removing the second layer comprises a second etch process different from the first etch process.

7. The method of claim 6, wherein the first etch process uses an etchant comprising a mixture of F₂, NH₃, Ar, or N₂.

8. A method comprising:
forming a stack of semiconductor layers on a substrate, the stack comprising:
a first silicon germanium (SiGe) layer on the substrate, the first SiGe layer having a first germanium (Ge) concentration;
a second SiGe layer on the first SiGe layer, the second SiGe layer having a second SiGe concentration greater than the first Ge concentration;
a third SiGe layer on the second SiGe layer, the third SiGe layer having the first Ge concentration; and
a silicon (Si) layer on the third SiGe layer;
patterning the stack to form a semiconductor structure;
forming a sacrificial gate over the semiconductor structure;
forming epitaxial regions adjacent to the sacrificial gate;
removing the sacrificial gate to form a recess;
selectively etching the first SiGe layer and the third SiGe layer through the recess to form an opening;
selectively etching the second SiGe layer through the recess to expand the opening; and
forming a replacement gate in the recess and the opening.

9. The method of claim 8, further comprising, before selectively etching the first SiGe layer and the third SiGe layer:
selectively etching a native oxide formed on the first SiGe layer and the third SiGe layer; and
performing a thermal treatment.

10. The method of claim 9, wherein the thermal treatment is performed in an atmosphere comprising Ar, N₂, or a mixture of Ar and N₂.

11. The method of claim 8, wherein the first SiGe layer and the third SiGe layer are selectively etched using an etchant comprising a mixture of F₂, ClF₃, HF, Ar, or N₂.

12. The method of claim 8, wherein the second SiGe layer is selectively etched using an etchant comprising a mixture of F₂, NH₃, Ar, or N₂.

13. The method of claim 8, further comprising, after selectively etching the first SiGe layer and the third SiGe layer, performing a thermal treatment.

14. The method of claim 8, further comprising, after selectively etching the second SiGe layer, performing a thermal treatment.

15. A method comprising:
forming a stack of semiconductor layers over a substrate, the stack comprising:
a first layer comprising a first semiconductor material over the substrate;
a second layer comprising a second semiconductor material over the first layer;
a third layer comprising the first semiconductor material over the second layer; and
a fourth layer comprising a third semiconductor material over the third layer;
patterning the stack to form a first semiconductor structure and a second semiconductor structure;
forming a first sacrificial gate over the first semiconductor structure, the first sacrificial gate having a first width;
forming a second sacrificial gate over the second semiconductor structure, the second sacrificial gate having a second width greater than the first width;
forming first epitaxial regions adjacent to the first sacrificial gate;
forming second epitaxial regions adjacent to the second sacrificial gate;
removing the first sacrificial gate to form a first recess;
removing the second sacrificial gate to form a second recess;
selectively removing the first layer and the third layer from the first semiconductor structure through the first recess to form a first opening;
selectively removing the first layer and the third layer from the second semiconductor structure through the second recess to form a second opening;
selectively removing the second layer from the first semiconductor structure through the first recess to expand the first opening;
selectively removing the second layer from the second semiconductor structure through the second recess to expand the second opening;
forming a first replacement gate in the first recess and the first opening; and
forming a second replacement gate in the second recess and the second opening.

16. The method of claim 15, wherein selectively removing the first layer and the third layer from the first semiconductor structure and selectively removing the first layer and the third layer from the second semiconductor structure comprises performing a first etch process.

17. The method of claim 16, wherein the first etch process is performed at a process pressure in a range from 10 mTorr to 500 mTorr and a process temperature in a range from 0° C. to 55° C.

18. The method of claim 16, wherein selectively removing the second layer from the first semiconductor structure and selectively removing the second layer from the second semiconductor structure comprises performing a second etch process different from the first etch process.

19. The method of claim 18, wherein the second etch process is performed at a process pressure in a range from 10 mTorr to 250 mTorr and a process temperature in a range from 60° C. to 80° C.

20. The method of claim 15, wherein the first semiconductor material comprises silicon germanium (SiGe) having a first germanium concentration, the second semiconductor material comprises SiGe having a second germanium concentration greater than the first germanium concentration, and the third semiconductor material comprise silicon (Si).
